(19) United States
(12) Patent Application Publication
(10) Pub. No.: US 2025/0081729 A1
(43) Pub. Date: Mar. 6, 2025

(54) DISPLAY DEVICE AND METHOD OF MANUFACTURING THE SAME

(71) Applicant: Samsung Display Co., LTD., Yongin-si (KR)

(72) Inventors: Soo Jung CHAE, Yongin-si (KR); Sung Joon KWAK, Yongin-si (KR); Jae Hong KIM, Yongin-si (KR); Tae Sun PARK, Yongin-si (KR); Jae Hyoung YOUN, Yongin-si (KR); Je Min LEE, Yongin-si (KR)

(73) Assignee: Samsung Display Co., LTD., Yongin-si (KR)

(21) Appl. No.: 18/626,440

(22) Filed: Apr. 4, 2024

(30) Foreign Application Priority Data
Aug. 29, 2023 (KR) 10-2023-0113680

(51) Int. Cl. H10K 59/121; H10K 59/12; H10K 59/131

(52) U.S. Cl. CPC H10K 59/1213; H10K 59/1201; H10K 59/131

(57) ABSTRACT

A display device includes a substrate including a display area and a driving circuit area, a first insulating layer, a second insulating layer on the first insulating layer, a first transistor in the display area, and including a first semiconductor pattern layer formed as a semiconductor layer on the second insulating layer, a first gate electrode on the first semiconductor pattern layer, and a first lower electrode overlapping the first semiconductor pattern layer, and a second transistor in the driving circuit area, and including a second semiconductor pattern layer formed as the semiconductor layer, a second gate electrode on the second semiconductor pattern layer, and a second lower electrode overlapping the second semiconductor pattern layer, wherein the first lower electrode is between the substrate and the first insulating layer, and the second lower electrode is between the first insulating layer and the second insulating layer.

### CROSS-REFERENCE TO RELATED APPLICATION(S)

This application claims priority to and benefits of Korean Patent Application No. 10-2023-0113680 under 35 U.S.C. § 119, filed on Aug. 29, 2023, in the Korean Intellectual Property Office, the entire contents of which are incorporated herein by reference.

### BACKGROUND

### 1. Technical Field

Embodiments relate to a display device and a method of manufacturing the display device.

### 2. Description of the Related Art

The importance of display devices has steadily increased with the development of multimedia technology. Accordingly, various types of display devices such as a liquid crystal display device or a light emitting display device have been developed.

### SUMMARY

Embodiments provide a display device capable of optimizing operating characteristics of a first transistor disposed in a display area and a second transistor disposed in a driving circuit area and a method of manufacturing the display device.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device including a substrate including a display area and a driving circuit area, a first insulating layer disposed on the substrate, a second insulating layer disposed on the first insulating layer, a first transistor disposed in the display area, and including a first semiconductor pattern layer formed as a semiconductor layer on the second insulating layer, a first gate electrode disposed on the first semiconductor pattern layer, and a first lower electrode overlapping the first semiconductor pattern layer, and a second transistor disposed in the driving circuit area, and including a second semiconductor pattern layer formed as the semiconductor layer, a second gate electrode disposed on the second semiconductor pattern layer, and a second lower electrode overlapping the second semiconductor pattern layer, wherein the first lower electrode is formed as a first conductive layer disposed between the substrate and the first insulating layer, and the second lower electrode is formed as a second conductive layer disposed between the first insulating layer and the second insulating layer.

In an embodiment, the first semiconductor pattern layer and the first lower electrode may be spaced apart from each other with the first insulating layer and the second insulating layer disposed between the first semiconductor pattern layer and the first lower electrode, and the second semiconductor pattern layer and the second lower electrode may be spaced apart from each other with the second insulating layer disposed between the second semiconductor pattern layer and the second lower electrode.

In an embodiment, the first semiconductor pattern layer and the first lower electrode may be spaced apart from each other by a first distance, and the second semiconductor pattern layer and the second lower electrode may be spaced apart from each other by a second distance smaller than the first distance.

In an embodiment, the first semiconductor pattern layer and the second semiconductor pattern layer may include an oxide semiconductor.

In an embodiment, the display device may further include a first gate insulating pattern layer disposed between the first semiconductor pattern layer and the first gate electrode and covering a part of the first semiconductor pattern layer.

In an embodiment, the first gate insulating pattern layer may have a shape and a size corresponding to a shape and a size of the first gate electrode and may expose another part of the first semiconductor pattern layer.

In an embodiment, the display device may further include a second gate insulating pattern layer disposed between the second semiconductor pattern layer and the second gate electrode and covering a part of the second semiconductor pattern layer.

In an embodiment, the second gate insulating pattern layer may have a shape and a size corresponding to a shape and a size of the second gate electrode and may expose another part of the second semiconductor pattern layer.

In an embodiment, the display device may further include an interlayer insulating layer covering the first gate electrode and the second gate electrode. The first transistor may further include a first source electrode and a first drain electrode disposed on the interlayer insulating layer and connected to different parts of the first semiconductor pattern layer, and the second transistor may further include a second source electrode and a second drain electrode disposed on the interlayer insulating layer and connected to different parts of the second semiconductor pattern layer.

In an embodiment, the first lower electrode may be connected to the first source electrode.

In an embodiment, the second lower electrode may be connected to the second gate electrode.

In an embodiment, the display device may further include a pixel disposed in the display area and including the first transistor.

In an embodiment, the pixel may further include a third transistor including a third semiconductor pattern layer formed as the semiconductor layer, a third gate electrode disposed on the third semiconductor pattern layer, and a third lower electrode formed as the second conductive layer and overlapping the third semiconductor pattern layer.

In an embodiment, the display device may further include a driving circuit disposed in the driving circuit area and including the second transistor.

In an embodiment, the driving circuit may output a gate signal that controls an operation of a pixel disposed in the display area.

According to an aspect of the disclosure, there is provided a method of manufacturing a display device, including providing a substrate including a display area and a driving circuit area, forming a first lower electrode on the substrate in the display area, forming a first insulating layer covering the first lower electrode on the substrate, forming a second lower electrode on the first insulating layer in the driving circuit area, forming a second insulating layer covering the second lower electrode on the first insulating layer, forming a first semiconductor pattern layer overlapping the first lower electrode and a second semiconductor pattern layer overlapping the second lower electrode on the second insulating layer, forming a third insulating layer covering the first semiconductor pattern layer and the second semiconductor pattern layer on the second insulating layer, and forming a first gate electrode overlapping the first semiconductor pattern layer and a second gate electrode overlapping the second semiconductor pattern layer on the third insulating layer.

In an embodiment, in the forming of the first semiconductor pattern layer and the second semiconductor pattern layer, the first semiconductor pattern layer and the second semiconductor pattern layer may be simultaneously formed of a same oxide semiconductor.

In an embodiment, the method may further include, by etching the third insulating layer, forming a first gate insulating pattern layer on a part of the first semiconductor pattern layer overlapping the first gate electrode, and forming a second gate insulating pattern layer on a part of the second semiconductor pattern layer overlapping the second gate electrode.

In an embodiment, the method may further include forming an interlayer insulating layer covering the first gate electrode and the second gate electrode on the second insulating layer.

In an embodiment, the method may further include forming at least one of a first drain electrode, a first source electrode, a second drain electrode, or a second source electrode, on the interlayer insulating layer. The first drain electrode and the first source electrode may be connected to the first semiconductor pattern layer, and the second drain electrode and the second source electrode may be connected to the second semiconductor pattern layer.

In accordance with the display device and the method of manufacturing the display device according to embodiments, the first transistor disposed in the display area and the second transistor disposed in the driving circuit area may be formed in different structures according to the operating characteristics required for each transistor. For example, the first transistor of a pixel may have a double gate structure including a first lower electrode disposed under a first semiconductor pattern layer of the first transistor and formed as a first conductive layer between the substrate and a first insulating layer. The second transistor of a driving circuit may have a double gate structure including a second lower electrode disposed under a second semiconductor pattern layer of the second transistor and formed as a second conductive layer on the first insulating layer.

In accordance with embodiments, the magnitude of the capacitance formed between the semiconductor pattern layer and the lower electrode of each transistor may be differentiated and/or optimized according to the characteristics required for each transistor. For example, the capacitance formed in the first transistor of each pixel is reduced or minimized, so that it is possible to prevent luminance variation of pixels and improve image quality. Further, the capacitance formed in the second transistor is increased to increase the on-current of the second transistor, so that it is possible to improve the output characteristics of the driving circuit and stably drive the pixels.

However, effects according to the embodiments are not limited to those above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic plan view illustrating a display panel of FIG. 1;

FIG. 3 is a schematic diagram of an equivalent circuit of a pixel according to an embodiment;

FIG. 4 is a schematic diagram showing a driving circuit of a first driver according to an embodiment;

FIG. 5 is a schematic diagram of an equivalent circuit illustrating a stage of the driving circuit according to an embodiment;

FIG. 6 is a schematic cross-sectional view illustrating a display panel according to an embodiment;

FIG. 7 is a schematic cross-sectional view illustrating the display panel according to an embodiment; and

FIGS. 8 to 18 are schematic cross-sectional views showing a method of manufacturing the display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another clement or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction D1, the axis of the second direction D2, and the axis of the third direction D3 are not limited to three axes of a rectangular coordinate system, such as the X, Y, and Z-axes, and may be interpreted in a broader sense. For example, the axis of the first direction D1, the axis of the second direction D2, and the axis of the third direction D3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

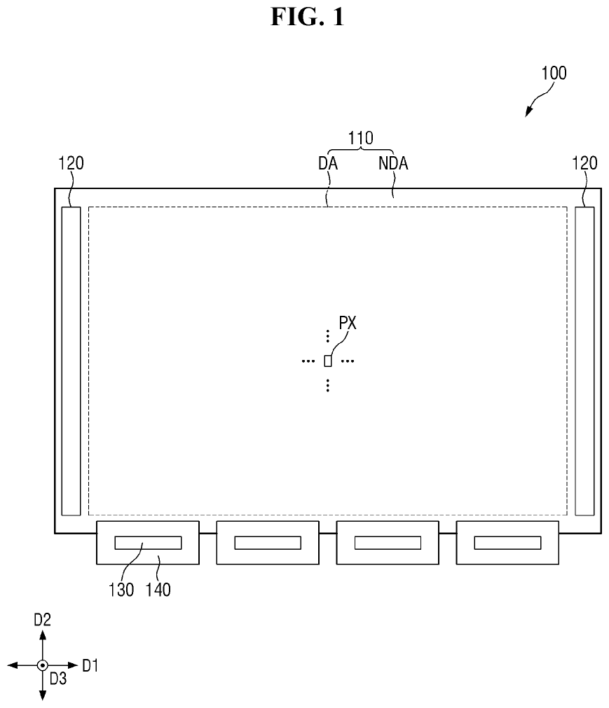

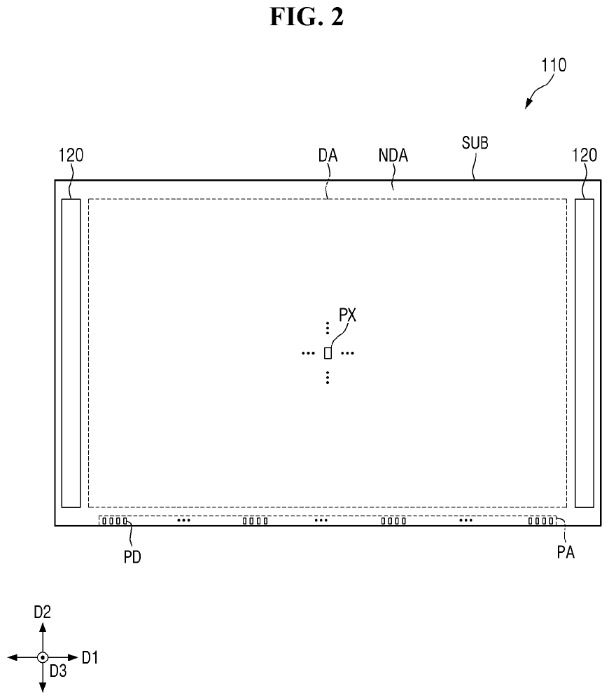

FIG. 1 is a schematic plan view illustrating a display device 100 according to an embodiment. FIG. 2 is a schematic plan view illustrating a display panel 110 of FIG. 1.

Referring to FIGS. 1 and 2, the display device 100 may be a device for displaying a moving image or a still image. The display device 100 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). These are examples, and the display device 100 may be applicable to various other types of electronic devices.

In an embodiment, the display device 100 may be a light emitting display device such as an organic light emitting display including an organic light emitting diode, a quantum dot light emitting display including a quantum dot light emitting layer, an inorganic light emitting display including an inorganic semiconductor, or an ultra-small light emitting display using an ultra-small light emitting diode such as a micro or nano light emitting diode (micro LED or nano LED), but embodiments are not limited thereto. For example, the display device 100 may be another type of display device other than a light emitting display device. In the following, embodiments in which the display device 100 is an organic light emitting display device will be described.

The display device 100 may include the display panel 110 including pixels PX, and a first driver 120 and a second driver 130 that supply driving signals to the pixels PX. The display device 100 may further include additional components. For example, the display device 100 may further include a power supply unit that supplies power voltages to the pixels PX, the first driver 120, and the second driver 130, and a timing controller that controls the operations of the first driver 120 and the second driver 130.

The display panel 110 may include a display area DA and a non-display area NDA (also referred to as a “bezel area”). The display area DA may be an area including the pixels PX to display an image. The non-display area NDA may be an area other than the display area DA, and an image may not be displayed in the non-display area NDA. In an embodiment, the non-display area NDA may be positioned around the display area DA and may surround the display area DA.

In FIGS. 1 and 2, a first direction DI, a second direction D2, and a third direction D3 are defined. In an embodiment, the first direction D1 and the second direction D2 may be perpendicular to each other, the first direction D1 and the third direction D3 may be perpendicular to each other, and the second direction D2 and the third direction D3 may be perpendicular to each other. For example, the first direction DI may be the horizontal direction (for example, a row direction or X-axis direction) of the display panel 110, and the second direction D2 may be the vertical direction (for example, a column direction or Y-axis direction) of the display panel 110. The third direction D3 may be the thickness direction (for example, a height direction or Z-axis direction) of the display panel 110.

In an embodiment, the display panel 110 may have a rectangular shape in plan view. For example, the display panel 110 may include two first sides extending in the first direction D1 and two second sides extending in the second direction D2 intersecting the first direction D1. Although FIGS. 1 and 2 illustrate the display panel 110 in which the first side in the horizontal direction is longer than the second side in the vertical direction, the shape of the display panel 110 is not limited thereto. For example, the display panel 110 may have a shape in which the second side in the vertical direction is longer than the first side in the horizontal direction, or the lengths of the first side and the second side are substantially the same as each other.

In an embodiment, the display panel 110 may include an angled corner (or curved corner) at a portion where the first side and the second side meet, but embodiments are not limited thereto. For example, the display panel 110 may include a rounded corner at a portion where the first side and the second side meet.

The planar shape of the display panel 110 is not limited to the illustrated rectangular shape, and it may be applied in various shapes. For example, the display panel 110 may have a square shape, a non-quadrilateral polygonal shape, a circular shape, an elliptical shape, an atypical shape, or another shape in plan view.

In an embodiment, the display panel 110 may be substantially flat on the plane defined by the first direction D1 and the second direction D2, and may have a uniform thickness in the third direction D3. In another embodiment, the display panel 110 may be provided in a three-dimensional shape having a curved surface or the like.

The display panel 110 may be provided as a panel having rigid characteristics so as not to be substantially deformed, or as a panel having flexible characteristics that can be transformed to be at least partially folded, bent, or rolled. The display panel 110 may be provided to the display device 100 without bending, or may be provided to the display device 100 in case of being partially bent.

The display panel 110 may include a substrate SUB and pixels PX disposed on the substrate SUB. The pixels PX may be disposed in the display area DA on the substrate SUB.

The substrate SUB, which is a base member for manufacturing or providing the display panel 110, may form the base surface of the display panel 110. The substrate SUB may include the display area DA and the non-display area NDA positioned around the display area DA.

The display area DA may have various shapes according to embodiments. For example, the display area DA may have a quadrilateral shape, a non-quadrilateral polygonal shape, a circular shape, an elliptical shape, an atypical shape, or another shape. In an embodiment, the display area DA may have a shape corresponding to the shape of the display panel 110, but embodiments are not limited thereto.

The display area DA may include pixel areas where the pixels PX are provided and/or disposed. For example, each pixel PX may be disposed in each pixel area positioned in the display area DA. In an embodiment, the display device 100 may be a light emitting display device, and each pixel PX may include a light emitting element positioned in each emission area and a pixel circuit connected to the light emitting element. In describing embodiments, the term “connect” may include electrical connection and/or physical connection.

Each pixel area may include an emission area where the light emitting element of the corresponding pixel is positioned and where the pixel emits light, and a pixel circuit area where circuit elements constituting the pixel circuit of the corresponding pixel are positioned. In an embodiment, the emission area and the pixel circuit area of each pixel PX may overlap each other, but embodiments are not limited thereto.

The pixels PX may be arranged in the display area DA. For example, the pixels PX may be arranged in the display area DA in a stripe structure, a delta structure, a pentile structure, or another arrangement structure.

The non-display area NDA may include a driving circuit area positioned on at least one side of the display area DA and a pad area PA where the pads PD are disposed. At least one driver, the pads PD, and/or wires may be disposed in the non-display area NDA.

At least one driver for driving the pixels PX, or a part of the driver may be disposed in the driving circuit area. For example, the circuit elements constituting the first driver 120 may be disposed in the driving circuit area on the substrate SUB. In an embodiment, the circuit elements of the first driver 120 may be formed in the display panel 110 together with the pixels PX.

Pads PD may be disposed in the pad area PA. At least one circuit board 140 may be disposed and/or bonded on the pad area PA. In an embodiment, circuit boards 140 connected to different pads PD may be disposed on the pad area PA. The pads PD may include signal pads and power pads for transmitting driving signals and power voltages required for driving the pixels PX and/or the first driver 120 into the display panel 110.

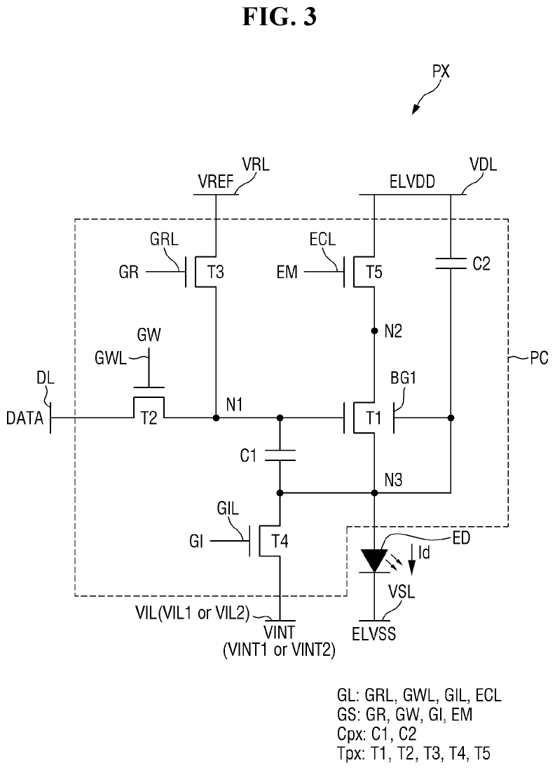

The first driver 120 and the second driver 130 may generate driving signals for controlling operation timing, luminance, and the like of the pixels PX, and may supply the generated driving signals to the pixels PX. For example, the first driver 120 may be a gate driver including a scan driver, and may be connected to the pixels PX through respective gate lines. The first driver 120 may provide gate signals (for example, driving signals that include a first gate signal GW of FIG. 3 and control the operation timing of the pixels PX) to the pixels PX. The second driver 130 may be a data driver including source driving circuits, and may be connected to the pixels PX through respective data lines. The second driver 130 may supply respective data signals to the pixels PX.

In an embodiment, at least one first driver of the first driver 120 or the second driver 130, or a part of the at least one first driver may be embedded in the display panel 110. For example, the first driver 120 or a part of the first driver 120 may be disposed or formed in the non-display area NDA of the display panel 110.

Although FIG. 1 illustrates that the first driver 120 is formed on sides (e.g., opposite sides) of the display area DA (for example, in the non-display area NDA on the left side and the right side of the display area DA), but the embodiments are not limited thereto. For example, in another embodiment, the first driver 120 may be disposed only on a side of the display area DA. In another embodiment, a part of the first driver 120 (for example, some of circuit elements constituting the first driver 120) are positioned in the non-display area NDA, and another portion of the first driver 120 (for example, the rest of the circuit elements constituting the first driver 120) may be positioned in a non-emission area (for example, an area between emission areas of the pixels PX) provided in the display area DA.

In an embodiment, the other driver of the first driver 120 and the second driver 130 or a part of the other driver may be disposed or formed outside the display panel 110 to be electrically connected to the display panel 110. For example, the second driver 130 or a part of the second driver 130 may be implemented by a multiple number of integrated circuit chips, and may be placed on the circuit board 140 electrically connected to the pixels PX of the display panel 110. In an embodiment, the second driver 130 and the timing controller may be integrated into separate integrated circuits, or may be integrated into an integrated chip. The second driver 130 may be implemented as at least one integrated circuit chip and mounted on the non-display area NDA of the display panel 110.

The circuit board 140 may be connected to the display panel 110 through the pads PD. In an embodiment, the circuit board 140 may be a flexible film such as a flexible printed circuit board (FPCB), a printed circuit board (PCB), or a chip on film (COF), but embodiments are not limited thereto. In an embodiment, the circuit board 140 may be connected to the timing controller and/or the power supply unit through another circuit board, connector, or the like.

FIG. 3 is a schematic diagram of an equivalent circuit of the pixel PX according to an embodiment. The pixel PX of FIG. 3 is an example, and the structure or type of the pixel PX may be changed in various ways according to embodiments.

Referring to FIG. 3 in addition to FIGS. 1 and 2, the pixel PX may include a light emitting element ED, and a pixel circuit PC connected to the light emitting element ED. The light emitting element ED may be a light source of the pixel PX, and it may be, for example, an organic light emitting diode, but embodiments are not limited thereto. The pixel circuit PC may control the emission time point and the luminance of the light emitting element ED.

The pixel circuit PC may include pixel transistors Tpx (also referred to as “transistors of a first group” or “transistors of the display area DA”), and at least one pixel capacitor Cpx. For example, the pixel circuit PC may include first to fifth pixel transistors T1 to T5, and first and second pixel capacitors C1 and C2. The structure of the pixel circuit PC or the types of the circuit elements constituting the pixel circuit PC may be changed in various ways according to embodiments. Although FIG. 3 illustrates an embodiment in which the pixel transistors Tpx are all N-type transistors, the types of pixel transistors Tpx are not limited thereto. For example, at least one pixel transistor Tpx may be formed of a P-type transistor.

The pixel circuit PC may supply a driving current Id to the light emitting element ED in response to the driving signals supplied from the first driver 120 and the second driver 130. For example, the pixel circuit PC may supply the driving current Id to the light emitting element ED in response to respective gate signals GS supplied from the first driver 120 through respective gate lines GL and a data signal DATA supplied from the second driver 130 through a data line DL.

The first pixel transistor TI may be a driving element of the pixel PX, in which a magnitude (or amount) of a source-drain current (e.g., the driving current Id) is determined according to a gate-source voltage. The second to fifth pixel transistors T2 to T5 may be switching elements that are turned on or off according to their own gate-source voltages (substantially, their own gate voltages). According to the type (for example, P-type or N-type) and/or operating conditions of each of the first to fifth pixel transistors T1 to T5, a first electrode of each of the first to fifth pixel transistors T1 to T5 may be a drain electrode (or a drain region), or a source electrode (or a source region), and a second electrode of each of the first to fifth pixel transistors T1 to T5 may be an electrode different from the first electrode. For example, in case that the first electrode is a drain electrode, the second electrode may be a source electrode.

The pixel PX may be connected to a first gate line GWL that transmits the first gate signal GW (e.g., a scan signal), a second gate line GIL that transmits a second gate signal GI, a third gate line GRL that transmits a third gate signal GR, an emission control line ECL that transmits an emission control signal EM, and the data line DL that transmits the data signal DATA. Further, the pixel PX may be connected to a first pixel power line VDL that transmits a first pixel voltage ELVDD (also referred to as “first pixel power voltage”), and a second pixel power line VSL that transmits a second pixel voltage ELVSS (also referred to as “second pixel power voltage”). In an embodiment, the pixel PX may be further connected to an initialization power line VIL that transmits an initialization voltage VINT (also referred to as “third pixel power voltage”), and a reference power line VRL that transmits a reference voltage VREF (also referred to as “fourth pixel power voltage”). In an embodiment, the initialization power line VIL may include initialization power lines VIL (e.g., a first initialization power line VIL1 and a second initialization power line VIL2) for transmitting the initialization voltages VINT having different magnitudes (e.g., a first initialization voltage VINT1 and a second initialization voltage VINT2).

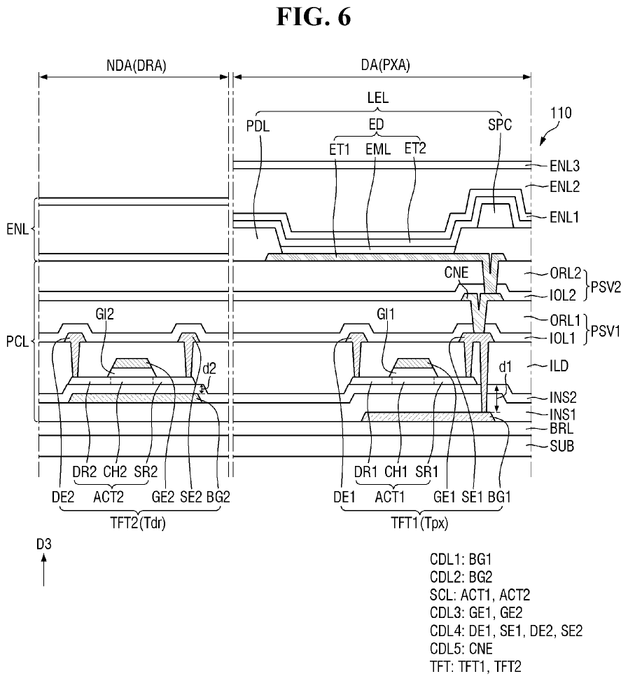

In an embodiment, the first to fifth pixel transistors TI to T5 may be positioned in respective pixel areas (e.g., a pixel area PXA of any one pixel PX provided in the display area DA of FIG. 6), and may be oxide transistors (also referred to as “oxide semiconductor transistors”) including an oxide semiconductor (for example, an oxide semiconductor material). For example, the semiconductor pattern layer (also referred to as “active pattern layer” or “active layer”) of each of the first to fifth pixel transistors T1 to T5 may be formed of an oxide semiconductor. However, embodiments are not limited thereto. For example, at least one pixel transistor Tpx may be formed of a semiconductor material (for example, amorphous silicon or polysilicon) other than an oxide semiconductor.

The oxide semiconductor may have high carrier mobility (for example, high electron mobility in the case of an N-type transistor) and low leakage current, so in case that a driving time of the oxide transistor is long, a voltage drop may not be large. For example, the pixel PX including an oxide transistor may be driven at a low frequency because the change in the luminance and/or the color of an image due to a voltage drop is not significant even in case that it is driven at a low frequency. In the case of the display device 100 in which the first to fifth pixel transistors T1 to T5 include an oxide semiconductor, the leakage current of the pixel PX may be reduced or prevented, and the power consumption may be reduced.

The oxide semiconductor may be sensitive to light, so that the amount of current or the like may be changed due to external light. In an embodiment, a lower electrode (also referred to as “counter gate electrode” or “bottom electrode”) may be disposed under the semiconductor pattern layer constituting at least one pixel transistor Tpx (for example, at least one of the first to fifth pixel transistors T1 to T5). For example, the lower electrode may be disposed under the semiconductor pattern layer of the pixel transistor Tpx including an oxide semiconductor. The lower electrode may be disposed to face the gate electrode with the semiconductor pattern layer of the corresponding pixel transistor Tpx disposed between the lower electrode and the gate electrode.

In describing the following embodiments, the lower electrode provided to at least one pixel transistor Tpx is referred to as “first lower electrode BG1.” By providing the first lower electrode BG1 to the pixel transistor Tpx, it is possible to prevent, reduce, or minimize the change in the amount of current of the pixel transistor Tpx due to light, and to stabilize the operating characteristics of the pixel transistor Tpx. The pixel transistor Tpx including the first lower electrode BG1 may have the operating characteristics corresponding to the capacitance (for example, a parasitic capacitance) formed between the first lower electrode BG1 and the semiconductor pattern layer.

The first pixel transistor T1 may include a gate electrode connected to a first node N1 (or a gate node), a first electrode (for example, a drain electrode or a drain region) connected to a second node N2, and a second electrode (for example, a source electrode or a source region) connected to a third node N3. In an embodiment, the first pixel transistor T1 may further include the first lower electrode BG1. For example, the first pixel transistor T1 may further include the first lower electrode BG1 (also referred to as “first bottom electrode”, “first bottom-gate electrode” or “first back-gate electrode”) connected to the third node N3. In case that the first lower electrode BG1 of the first pixel transistor T1 is connected to the third node N3 similarly to the second electrode of the first pixel transistor T1, the operating characteristics of the first pixel transistor T1 may be improved. The first electrode of the first pixel transistor T1 may be connected to the first pixel power line VDL via the fifth pixel transistor T5, and the second electrode of the first pixel transistor T1 may be connected to the light emitting element ED. The first pixel transistor T1 may function as a driving element of the pixel PX, and may control the magnitude (for example, the amount of current) of the driving current Id flowing to the light emitting element ED in response to the data signal DATA transmitted according to the switching operation of the second pixel transistor T2.

In an embodiment, at least one transistor among the second to fifth pixel transistors T2 to T5 may also include the lower electrode (for example, each first lower electrode BG1). The at least one transistor may have the operating characteristics corresponding to the capacitance formed between the lower electrode and the semiconductor pattern layer. In an embodiment, the lower electrode of the at least one transistor may be connected to an electrode (for example, a gate electrode) of the transistor.

The second pixel transistor T2 may include a gate electrode connected to the first gate line GWL, a first electrode connected to the data line DL, and a second electrode connected to the first node N1. The second pixel transistor T2 may be turned on by the first gate signal GW (for example, the gate-on voltage of the first gate signal GW) transmitted to the first gate line GWL to connect the data line DL and the first node N1. Accordingly, the data signal DATA transmitted through the data line DL may be sent to the first node N1.

The third pixel transistor T3 may include a gate electrode connected to the third gate line GRL, a first electrode connected to the reference power line VRL, and a second electrode connected to the first node N1. The third pixel transistor T3 may be turned on by the third gate signal GR transmitted through the third gate line GRL and transmit the reference voltage VREF transmitted to the reference power line VRL to the first node N1.

The fourth pixel transistor T4 may include a gate electrode connected to the second gate line GIL, a first electrode connected to the third node N3, and a second electrode connected to the initialization power line VIL. The fourth pixel transistor T4 may be turned on by the second gate signal GI transmitted through the second gate line GIL and transmit the initialization voltage VINT transmitted to the initialization power line VIL to the third node N3.

The fifth pixel transistor T5 may include a gate electrode connected to the emission control line ECL, a first electrode connected to the first pixel power line VDL, and a second electrode connected to the second node (or the first electrode of the first pixel transistor T1). The fifth pixel transistor T5 may be turned on by the emission control signal EM (for example, the gate-on voltage of the emission control signal EM) transmitted to the emission control line ECL to control the emission time point of the pixel PX.

The first pixel capacitor C1 may be connected between the first node N1 and the third node N3. For example, the first pixel capacitor C1 may be connected between the second electrode and the gate electrode of the first pixel transistor T1. The first pixel capacitor C1 may be a storage capacitor of the pixel PX, and may store a threshold voltage of the first pixel transistor T1 and a voltage corresponding to the data signal DATA (e.g., a data voltage).

The second pixel capacitor C2 may be connected between the first pixel power line VDL and the third node N3. In an embodiment, the capacity of the second pixel capacitor C2 may be less than that of the first pixel capacitor C1.

The light emitting element ED may be connected between the third node N3 and the second pixel power line VSL. For example, the light emitting element ED may include a first electrode (for example, an anode electrode or a pixel electrode), a second electrode (for example, a cathode electrode or a counter electrode) facing the first electrode, and a light emitting layer disposed between the first electrode and the second electrode. The first electrode of the light emitting element ED may be connected to the third node N3. The second electrode of the light emitting element ED may be connected to the second pixel power line VSL. In an embodiment, the second electrode of the light emitting element ED may be a common electrode shared by the pixels PX. The light emitting element ED may emit light with a luminance corresponding to the driving current Id during a time period in which the driving current Id is supplied from the pixel circuit PC.

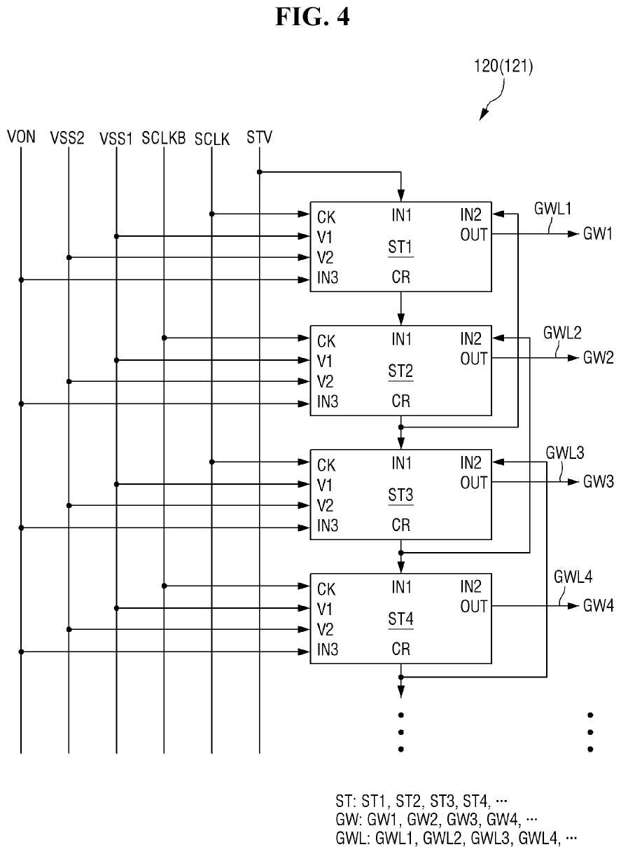

FIG. 4 is a schematic diagram showing a driving circuit 121 of the first driver 120 according to an embodiment. FIG. 4 illustrates one type of driving circuit 121 included in the first driver 120 (or constituting the first driver 120) as an example for showing the configuration of the first driver 120. In an embodiment, the driving circuit 121 may be a scan driving circuit (or a scan driver) that outputs the first gate signals GW of the pixels PX, but embodiments are not limited thereto. For example, the driving circuit 121 of FIG. 4 is illustrated as an example, and the type, structure, number, and/or input/output signals of the first driver 120 or the driving circuit 121 constituting the first driver 120 may vary in various ways according to embodiments.

In the following description, the term “previous stages (or previous-step stages)” may refer to stages that generate the first gate signals GW whose phase is faster than the first gate signal GW outputted at a specific stage as a reference. Also, the term “next stages (or next-step stages)” may refer to stages that generate the first gate signals GW whose phase is later than the first gate signal GW outputted at the specific stage as the reference.

Referring to FIG. 4 in addition to FIGS. 1 to 3, the driving circuit 121 may include stages ST.

Each of the stages ST may receive multiple driving power voltages and multiple external signals. The stages ST may output the respective first gate signals GW based on the multiple driving power voltages (or driving voltages) and the multiple external signals inputted thereto. In an embodiment, the driving power voltages may include at least one of a first driving voltage VON (also referred to as “control voltage”) that is a high potential voltage, a second driving voltage VSS1 (also referred to as “first driving power voltage” or “first low-potential driving voltage”) that is a first low-potential voltage, or a third driving voltage VSS2 (also referred to as “second driving power voltage” or “second low-potential driving voltage”) that is a second low-potential voltage. For example, the multiple external signals may include at least one of a scan start signal STV, a carry signal inputted from the previous stage, a reset signal inputted from the next stage, or a scan clock signal (e.g., a first scan clock signal SCLK and a second scan clock signal SCLKB), but embodiments are not limited thereto. In an embodiment, the third driving voltage VSS2 may have a potential, which is lower than that of the second driving voltage VSS1.

The first gate signal GW outputted from each stage ST (for example, a first gate signal GW1 outputted from a first stage ST1 of FIG. 4) may be supplied to the next stage (for example, a second stage ST2) as a carry signal. Each stage ST may output the first gate signal GW to the gate line GWL connected thereto in response to a carry signal (e.g., a first carry signal) inputted from the previous stage. Among the stages ST, the first stage ST1 may receive the scan start signal STV from the outside as the carry signal.

The first gate signal GW outputted from each stage ST may be supplied to the previous stage as a reset signal (e.g., a second carry signal). Each stage ST may transit the potential of an output node from a high-potential voltage to a second low-potential voltage (e.g., the third driving voltage VSS2) in response to the reset signal inputted from the next stage.

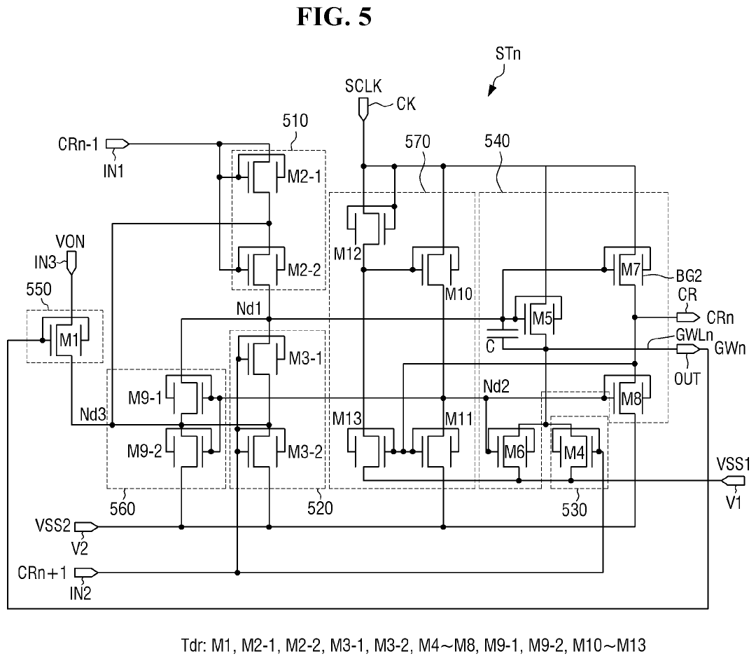

The stages ST may output the first gate signals GW in response to the scan start signal STV. For example, the stages ST may sequentially output the first gate signals GW to the first gate lines GWL in response to the scan start signal STV. For example, the n^{th} (n is a natural number) stage (for example, the n^{th} stage STn of FIG. 5) may output the n^{th} first gate signal GWn of FIG. 5 (e.g., GW1, GW2, GW3, GW4, . . . of FIG. 4)) to the n^{th} first gate line GWLn of FIG. 5 (e.g., GWL1, GWL2, GWL3, GWL4, . . . of FIG. 4). The scan start signal STV for controlling the output timing of the first gate signal GW1 (for example, a first scan signal) may be supplied to the first stage ST1.

Each of the stages ST may include a first input terminal IN1, a second input terminal IN2, a third input terminal IN3, a scan clock input terminal CK, a first power input terminal V1, a second power input terminal V2, a carry output terminal CR, and an output terminal OUT.

Each of the stages ST may receive the first scan clock signal SCLK or the second scan clock signal SCLKB through the scan clock input terminal CK. For example, the odd-numbered stages ST1, ST3, . . . may receive the first scan clock signal SCLK, in case that the even-numbered stages ST2, ST4, . . . receive the second scan clock signal SCLKB.

The first scan clock signal SCLK may be a square wave signal (or pulse signal) that repeats a logic high level and a logic low level. The logic high level may correspond to a gate-on voltage, and the logic low level may correspond to a gate-off voltage. For example, the logic high level may be a gate-high voltage with a voltage value in a range of about 10V and about 30V, and the logical low level may be a gate-low voltage with a voltage value in a range of about −16V and about −3V.

The second scan clock signal SCLKB may be a square wave signal (or pulse signal) that repeats the logic high level and the logic low level. In an embodiment, the second scan clock signal SCLKB may be set as a signal having the same cycle as the first scan clock signal SCLK but having an inverted phase. However, this is an example, and the waveform relationship between the first scan clock signal SCLK and the second scan clock signal SCLKB is not limited thereto. For example, a part of the logic high level period of the first scan clock signal SCLK and a part of the logic high level period of the second scan clock signal SCLKB may overlap.

For example, the number of the scan clock signals supplied to one stage is not limited to the above example. For example, two or more scan clock signals may be applied to each of the stages ST.

The first input terminal IN1 may receive the scan start signal STV or a carry signal of the previous stage. For example, the scan start signal STV may be applied to the first input terminal IN1 of the first stage ST1, and the carry signal of the previous stage may be applied to the first input terminal IN1 of each of the stages ST2, ST3, ST4, . . . other than the first stage ST1.

The second input terminal IN2 may receive a carry signal of the next stage. For example, the carry signal of the next stage may be one of the carry signals supplied after the lapse of a certain time from the output of the carry signal of the current stage.

The third input terminal IN3 may receive the first driving voltage VON. In an embodiment, the first driving voltage VON may be a high-potential voltage to be supplied to the source electrode of at least one transistor included in each of the stages ST. For example, the first driving voltage VON may be a constant voltage near the logic high level (e.g., the gate-on voltage) of the first scan clock signal SCLK. For example, the first driving voltage VON may have a voltage value in a range of about 10V to about 30V.

In an embodiment, the first driving voltage VON and the scan clock signal SCLK or SCLKB may be the same as each other. For example, each of the stages ST may receive the same clock signal through the scan clock input terminal CK and the third input terminal IN3.

The carry output terminal CR may output a carry signal. The carry signal may be provided to the first input terminal IN1 of the next stage.

The output terminal OUT may output the first gate signal GW generated at each stage ST. The first gate signal GW may be supplied to the pixel PX through the first gate line GWL corresponding to the pixel PX.

The first power input terminal V1 may be supplied with the second driving voltage VSS1, and the second power input terminal V2 may be supplied with the third driving voltage VSS2. The second driving voltage VSS1 and the third driving voltage VSS2 may be set to be the gate-off voltage. In an embodiment, the second driving voltage VSS1 and the third driving voltage VSS2 may be the same as each other. In an embodiment, the voltage level of the third driving voltage VSS2 may be less than the voltage level of the second driving voltage VSS1. For example, the second driving voltage VSS1 may be set in a range of about −14V to about −1V, and the third driving voltage VSS2 may be set in a range of about −16V to about −3V.

FIG. 5 is a schematic diagram of an equivalent circuit illustrating a stage ST (or STn) of the driving circuit 121 according to an embodiment. FIG. 5 shows the n^{th} stage STn included in the aforementioned driving circuit 121 (or constituting the driving circuit 121) as an example for showing the configuration of the driving circuit 121. The n^{th} stage STn of FIG. 5 is an example, and the structure, input/output signals, and/or operating method of the n^{th} stage STn may be variously changed according to embodiments.

Although FIG. 5 illustrates an embodiment in which driver transistors Tdr (also referred to as “second group transistors” or “transistors of built-in driving circuit”) constituting the n^{th} stage STn are N-type transistors), the type of the driver transistors Tdr is not limited thereto. For example, at least one driver transistor Tdr may be formed of a P-type transistor.

Referring to FIG. 5 in addition to FIGS. 1 to 4, the n^{th} stage STn may include a first input unit 510, a second input unit 520, a first controller 530, an output unit 540, and a leakage controller 550. In an embodiment, the n^{th} stage STn may further include a second controller 560 and a third controller 570.

In an embodiment, the driver transistors Tdr included in the n^{th} stage STn may be positioned in the driving circuit area (for example, the driving circuit area where the first driver 120 is disposed in the non-display area NDA of the display panel 110) of the display panel 110. In an embodiment, the driver transistors Tdr may be oxide transistors including an oxide semiconductor (for example, an oxide semiconductor material). For example, a semiconductor pattern layer of each of the driver transistors Tdr may be formed of an oxide semiconductor. In an embodiment, the driver transistors Tdr and the pixel transistors Tpx may be formed simultaneously using the same oxide semiconductor. For example, semiconductor pattern layers of the driver transistors Tdr and the pixel transistors Tpx may include the same oxide semiconductor, and may be disposed on the same layer on the substrate SUB. However, embodiments are not limited thereto. For example, at least one driver transistor Tdr may be formed of a semiconductor material (for example, amorphous silicon or polysilicon) other than an oxide semiconductor.

Each of the driver transistors Tdr may or may not include a lower electrode (for example, a lower electrode disposed under the semiconductor pattern layer and facing the gate electrode with the semiconductor pattern layer disposed between the lower electrode and the gate electrode) overlapping the semiconductor pattern layer. In an embodiment, the driver transistors Tdr may include the respective lower electrodes disposed under the semiconductor pattern layers. In describing the following embodiments, the lower electrode provided to each of the driver transistors Tdr is referred to as “second lower electrode BG2.” By providing the second lower electrodes BG2 to each of the driver transistors Tdr, the operating characteristics of the driver transistors Tdr may be improved and/or stabilized. The driver transistor Tdr including the second lower electrode BG2 may have the operating characteristics corresponding to the capacitance (for example, a parasitic capacitance) formed between the second lower electrode BG2 and the semiconductor pattern layer.

In an embodiment, at least one driver transistor Tdr may include the second lower electrode BG2 (also referred to as “second bottom electrode”, “second bottom-gate electrode” or “second back-gate electrode”) connected to the gate electrode of the transistor. For example, some driver transistors Tdr including the driver transistors Tdr of the output unit 540 that perform a pull-up or pull-down operation, or all the driver transistors Tdr constituting the stage STn may be transistors of a double gate structure including the respective second lower electrodes BG2 connected to the respective gate electrodes. FIG. 5 illustrates the stage STn in which all the driver transistors Tdr are formed in a double gate structure.

By forming the driver transistors Tdr in a double gate structure, it is possible to improve the operating characteristics of the driver transistors Tdr. For example, by forming the driver transistors Tdr in a double gate structure, it is possible to improve off characteristics and switching speeds of the driver transistors Tdr, ensure an additional voltage tolerance range, reduce a leakage current, and improve voltage stability.

The first input unit 510 may control the voltage of a first node Nd1 in response to the scan start signal STV or a carry signal CRn−1 of the previous stage supplied to the first input terminal IN1. The voltage of the first node Nd1 may be a voltage for controlling the outputs of the n^{th} first gate signal (hereinafter referred to as “n^{th} scan signal GWn”) and the n^{th} carry signal CRn. For example, the voltage of the first node Nd1 may be a voltage for controlling the pull-up of the n^{th} carry signal CRn and the n^{th} scan signal GWn.

In an embodiment, the first input unit 510 may include second driver transistors (for example, a second-first driver transistor M2-1 and a second-second driver transistor M2-2) connected in series between the first input terminal IN1 and the first node Nd1. Gate electrodes of the second driver transistors M2-1 and M2-2 may be connected to the first input terminal IN1 in common.

The first input unit 510 may transmit the gate-on voltage (e.g., logic high level) of the (n−1)^{th} carry signal CRn-1 to the first node Nd1. For example, the first input unit 510 may pre-charge the voltage of the first node Nd1 by using the gate-on voltage of the (n−1)^{th} carry signal CRn−1.

A common node between the second driver transistors M2-1 and M2-2 may correspond to the third node Nd3. For example, the common node between the second driver transistors M2-1 and M2-2 may be connected to the third node Nd3.

In case that the voltage of the first node Nd1 is the high level of the gate-on voltage, a leakage current may be generated (or occurred) from the first node Nd1 to the first input unit 510 in case that the voltage of the common node between the second driver transistors M2-1 and M2-2 is lower than a selectable/selected reference value. For example, in case that the threshold voltage is negatively shifted due to degradation of the second driver transistors M2-1 and M2-2, a leakage current may be generated (or occurred) from the first node Nd1 to the first input unit 510.

In each oxide transistor, a threshold voltage Vth may be shifted to a negative value (e.g., negatively shifted) due to degradation or the like. For example, the leakage current of the oxide transistor in a turn-off state may be increased, so that the stage STn may operate abnormally.

A high voltage level of the gate-on voltage may be applied to the common node between the second driver transistors M2-1 and M2-2 in the state that the first node Nd1 is charged with the gate-on voltage. For example, the (n−1)^{th} carry signal CRn−1 may have the gate-off voltage, and the gate-off voltage of the (n−1)^{th} carry signal CRn−1 may be supplied to gate electrodes of the second driver transistors M2-1 and M2-2. Therefore, a gate-source voltage Vgs of the second-second driver transistor M2-2 may be maintained at a very low value (e.g., a negative value), and in case that the second driver transistors M2-1 and M2-2 are degraded, a current leakage from the first node Nd1 to the first input unit 510 may be prevented.

The second input unit 520 may control the voltage of the first node Nd1 in response to a reset signal (e.g., an (n+1)^{th} carry signal CRn+1) of the next stage. In an embodiment, the second input unit 520 may provide a voltage of the third driving voltage VSS2 to the first node Nd1 in response to the (n+1)^{th} carry signal CRn+1. For example, the second input unit 520 may discharge the voltage of the first node Nd1 having a certain high-potential voltage.

The second input unit 520 may include third driver transistors (for example, a third-first driver transistor M3-1 and a third-second driver transistor M3-2) connected in series between the first node Nd1 and the second power input terminal V2. Gate electrodes of the third driver transistors M3-1 and M3-2 may be connected to the second input terminal IN2 in common.

A common node between the third transistors M3-1 and M3-2 may correspond to the third node Nd3. For example, the common node between the third driver transistors M3-1 and M3-2 may be connected to the third node Nd3.

The first controller 530 may control the voltage of the output terminal OUT that outputs the n^{th} scan signal GWn in response to the (n+1)^{th} carry signal CRn+1. In an embodiment, the first controller 530 may provide a voltage of the second driving voltage VSS1 to the output terminal OUT in response to the (n+1)^{th} carry signal CRn+1.

In an embodiment, the first controller 530 may include a fourth driver transistor M4 connected between the output terminal OUT and the first power input terminal V1. A gate electrode of the fourth driver transistor M4 may be connected to the second input terminal IN2. The fourth driver transistor M4 may discharge the voltage of the output terminal OUT to the voltage of the second driving voltage VSS1.

The output unit 540 may be connected to the scan clock input terminal CK, the first power input terminal V1, and the second power input terminal V2. The output unit 540 may output the n^{th} scan signal GWn corresponding to the scan clock signal SCLK and the n^{th} carry signal CRn to the output terminal OUT and the carry output terminal CR, respectively, in response to the voltage of the first node Nd1 and the voltage of the second node Nd2. The voltage of the second node Nd2 may control the gate-off voltage (e.g., logic low level) states of the n^{th} scan signal GWn and the n^{th} carry signal CRn. For example, the voltage of the second node Nd2 may be a voltage for controlling the pull-down of the n^{th} carry signal CRn and the n^{th} scan signal GWn. In an embodiment, the output unit 540 may include fifth to eighth driver transistors M5 to M8 and a driving capacitor C.

The fifth driver transistor M5 may be connected between the scan clock input terminal CK and the output terminal OUT. The fifth driver transistor M5 may include a gate electrode connected to the first node Nd1. The fifth driver transistor M5 may supply the gate-on voltage to the output terminal OUT in response to the voltage of the first node Nd1. For example, the fifth driver transistor M5 may function as a pull-up buffer.

The sixth driver transistor M6 may be connected between the output terminal OUT and the first power input terminal V1. The sixth driver transistor M6 may include a gate electrode connected to the second node Nd2. The sixth driver transistor M6 may supply the gate-off voltage to the output terminal OUT in response to the voltage of the second node Nd2. For example, the sixth driver transistor M6 may hold the voltage of the output terminal OUT at the gate-off voltage level (e.g., logic low level).

The seventh driver transistor M7 may be connected between the scan clock input terminal CK and the carry output terminal CR. The seventh driver transistor M7 may include a gate electrode connected to the first node Nd1. The seventh driver transistor M7 may supply the gate-on voltage to the carry output terminal CR in response to the voltage of the first node Nd1. For example, the seventh driver transistor M7 may function as a pull-up buffer.

The eighth driver transistor M8 may be connected between the carry output terminal CR and the second power input terminal V2. The eighth driver transistor M8 may include a gate electrode connected to the second node Nd2. The eighth driver transistor M8 may supply the gate-off voltage to the carry output terminal CR in response to the voltage of the second node Nd2. For example, the eighth driver transistor M8 may hold the voltage of the carry output terminal CR at the gate-off voltage level (e.g., logic low level).

The driving capacitor C may be connected between the first node Nd1 and the output terminal OUT. The driving capacitor C may function as a boosting capacitor. For example, the driving capacitor C may raise (or bootstrap) the voltage of the first node Nd1 in response to a voltage rise of the output terminal OUT in case that the fifth driver transistor M5 is turned on. Accordingly, the fifth driver transistor M5 may stably maintain a turn-on state for a period of time.

The second controller 560 may hold the voltage of the first node Nd1 to a gate-off voltage in response to the voltage of the second node Nd2. In an embodiment, the second controller 560 may provide a voltage of the third driving voltage VSS2 (e.g., the gate-off voltage) to the first node Nd1 in response to the voltage of the second node Nd2.

In an embodiment, the second controller 560 may include ninth driver transistors (e.g., a ninth-first driver transistor M9-1 and a ninth-second driver transistor M9-2) connected in series between the first node Nd1 and the second power input terminal V2. Gate electrodes of the ninth driver transistors M9-1 and M9-2 may be connected to the second node Nd2 in common.

A common node between the ninth driver transistors M9-1 and M9-2 may correspond to the third node Nd3. For example, the common node between the ninth driver transistors M9-1 and M9-2 may be electrically connected to the third node Nd3.

Although the two second driver transistors M2-1 and M2-2, the two third driver transistors M3-1 and M3-2, and the two ninth driver transistors M9-1 and M9-2 are illustrated in FIG. 5, the number of the driver transistors Tdr connected in series is not limited thereto. For example, in case that three or more third driver transistors are connected in series, at least one common node between these third driver transistors may be electrically connected to the third node Nd3.

The third controller 570 may control the voltage of the second node Nd2 in response to the scan clock signal SCLK and the n^{th} carry signal CRn. In an embodiment, the third controller 570 may transmit the scan clock signal SCLK to the second node Nd2 in response to the scan clock signal SCLK, and supply the gate-off voltage to the second node Nd2 in response to the n^{th} carry signal CRn.

The voltage of the second node Nd2 may control the gate-off voltage (e.g., logic low level) states of the n^{th} scan signal GWn and the n^{th} carry signal CRn. For example, the voltage of the second node Nd2 may be a voltage for controlling the pull-down of the n^{th} carry signal CRn and the n^{th} scan signal GWn.

The third controller 570 may include tenth to thirteenth driver transistors M10 to M13.

The tenth driver transistor M10 may be connected between the scan clock input terminal CK and the second node Nd2. A gate electrode of the tenth driver transistor M10 may be connected to a common node of the twelfth and thirteenth driver transistors M12 and M13. The tenth driver transistor M10 may supply the scan clock signal SCLK to the second node Nd2 in response to the scan clock signal SCLK.

The eleventh driver transistor M11 may be connected between the second node Nd2 and the second power input terminal V2.

The twelfth and thirteenth driver transistors M12 and M13 may be connected in series between the scan clock input terminal CK and the first power input terminal V1. A gate electrode of the twelfth driver transistor M12 may be connected to the scan clock input terminal CK. Gate electrodes of the eleventh and thirteenth driver transistors M11 and M13 may be connected to the carry output terminal CR in common.

In case that the n^{th} carry signal CRn is outputted (for example, in case that the n^{th} carry signal CRn has the gate-on voltage), the thirteenth driver transistor M13 may be turned on to turn off the tenth driver transistor M10, and the eleventh driver transistor M11 may be turned on to supply a voltage of the third driving voltage VSS2 to the second node Nd2. Accordingly, in case that the n^{th} carry signal CRn is outputted, the second node Nd2 may have a gate-off voltage.

In an embodiment, the voltage level of the third driving voltage VSS2 may be less than the voltage level of the second driving voltage VSS1. For example, the voltage of the third driving voltage VSS2, which is lower than the voltage of the second driving voltage VSS1, may be provided to the second node Nd2 by the operation of the eleventh driver transistor M11. This may be performed to prevent an unintended operation of the sixth driver transistor M6 and/or the eighth driver transistor M8 due to the ripple of the voltage of the second node Nd2 in case that the voltage of the second node Nd2 changes from the gate-on voltage to the gate-off voltage. Accordingly, an electrode of the eleventh driver transistor M11 may be connected to the third driving voltage VSS2, which is lower than the voltage of the second driving voltage VSS1.

The leakage controller 550 may supply the first driving voltage VON supplied to the third input terminal IN3 to the first input unit 510, the second input unit 520, and the second controller 560 in response to one of the n^{th} scan signal GWn and the n^{th} carry signal CRn. In an embodiment, the leakage controller 550 may include a first driver transistor M1 connected between the third input terminal IN3 and the third node Nd3. The first driver transistor M1 may include a gate electrode that receives the n^{th} scan signal GWn.

The first driver transistor M1 may supply, in response to the n^{th} scan signal GWn, the first driving voltage VON to common nodes of the driver transistors Tdr respectively connected in series to the first node Nd1. Accordingly, in case that the first node Nd1 is charged (for example, in case that the voltage of the first node Nd1 is boosted), the first driving voltage VON of a high potential may be applied to an electrode of the second driver transistor (e.g., the second-second driver transistor M2-2), an electrode of the third driver transistor (e.g., the third-first driver transistor M3-1), and an electrode of the ninth driver transistor (e.g., the ninth-first driver transistor M9-1). For example, in case that the first node Nd1 is charged, the third node Nd3 may be charged with the high-potential voltage by the first driving voltage VON. Therefore, in case that the voltage of the first node Nd1 is boosted, the gate-source voltage Vgs of each of the second-second driver transistor M2-2, the third-first driver transistor M3-1, and the ninth-first driver transistor M9-1 may have a negative value, and the gate-source voltage Vgs of each of the second-second driver transistor M2-2, the third-first driver transistor M3-1, and the ninth-first driver transistor M9-1 may be maintained at a value, which is much smaller than threshold voltages of them. Accordingly, the leakage current occurred from the first node Nd1 through the second-second driver transistor M2-2, the third-first driver transistor M3-1, and the ninth-first driver transistor M9-1 may be prevented or minimized.

FIG. 6 is a schematic cross-sectional view illustrating the display panel 110 according to an embodiment. For example, FIG. 6 illustrates a part of the display area DA and a part of the non-display area NDA of the display panel 110.

In FIG. 6, as an example of circuit elements that may be provided or placed in a panel circuit layer PCL of the display panel 110, any one pixel transistor Tpx (also referred to as “first transistor TFT1”) and any one driver transistor Tdr (also referred to as “second transistor TFT2”) are illustrated.

Further, although FIG. 6 illustrates the light emitting display panel including the light emitting element ED (for example, an organic light emitting diode) as an example of the display panel 110 to which embodiments are applicable, the embodiments are not limited thereto. For example, the display panel 110 may include a light emitting element of another type and/or structure, or may be a display panel of another type and/or structure other than the light emitting display panel.

Referring to FIG. 6 in addition to FIGS. 1 to 5, the display panel 110 may include the substrate SUB (also referred to as “base member” or “base layer”), the panel circuit layer PCL, a light emitting element layer LEL, and an encapsulation layer ENL. The panel circuit layer PCL, the light emitting element layer LEL, and the encapsulation layer ENL may be disposed or provided to overlap each other on the substrate SUB. For example, with respect to the display area DA, the panel circuit layer PCL, the light emitting element layer LEL, and the encapsulation layer ENL may be sequentially arranged or formed on the substrate SUB along the third direction D3. However, the embodiments are not limited thereto, and the mutual positions of the panel circuit layer PCL, the light emitting element layer LEL, and the encapsulation layer ENL may be changed. For example, the panel circuit layer PCL and the light emitting element layer LEL may be integral with each other, or the light emitting element layer LEL may be disposed above the panel circuit layer PCL.

In an embodiment, the display panel 110 may further include additional elements provided above and/or under the encapsulation layer ENL. For example, the display panel 110 may further include at least one of a sensor layer (for example, a touch sensor layer), an optical layer (for example, a color filter layer and/or a wavelength conversion layer), or a passivation layer (for example, a passivation film, an insulating layer, an upper substrate, and/or a window). Each of the sensor layer, the optical layer, and/or the passivation layer may be provided above the encapsulation layer ENL or may be provided between the light emitting element layer LEL and the encapsulation layer ENL. In an embodiment, the sensor layer, the optical layer and/or the passivation layer may be provided on the display panel 110. For example, the sensor layer, the optical layer and/or the passivation layer may be integrally manufactured with the display panel 110. In another embodiment, the sensor layer, the optical layer and/or the passivation layer may be manufactured separately from the display panel 110 and attached to the display panel 110 via an adhesive layer or the like.

The substrate SUB, which is a base member for forming the display panel 110, may be a substrate (or film) having rigid or flexible characteristics. In an embodiment, the substrate SUB may be a substrate including an insulating material such as glass or the like and having rigid characteristics, and may not be bent. In another embodiment, the substrate SUB may be a flexible substrate that includes polyimide or another insulating material and may be bendable, foldable, or rollable. For example, the substrate SUB may be bent or may be flat. The type and/or material of the substrate SUB may change according to embodiments.

The substrate SUB may include the display area DA and the non-display area NDA. In an embodiment, the display area DA may include the pixel areas PXA corresponding to the pixels PX, and the non-display area NDA may include a driving circuit area DRA. For example, the pixel areas PXA where the pixels PX are disposed may be defined in the display area DA, and the driving circuit area DRA where the first driver 120 is disposed may be defined in the non-display area NDA.

In an embodiment, a barrier layer BRL (or a buffer layer) may be provided on the substrate SUB. For example, the display panel 110 may further include the barrier layer BRL disposed between the substrate SUB and the panel circuit layer PCL. In another embodiment, the display panel 110 may not include the barrier layer BRL, and for example, the panel circuit layer PCL may be disposed on (e.g., directly on) the substrate SUB.

The barrier layer BRL may include at least one inorganic insulating layer including an inorganic insulating material (e.g., silicon nitride, silicon oxide, silicon oxynitride, titanium oxide, aluminum oxide, or another inorganic insulating material). The barrier layer BRL may protect the pixels PX from moisture permeating through the substrate SUB that is susceptible to moisture permeation. The material of the barrier layer BRL may be variously changed according to embodiments.

The panel circuit layer PCL may be disposed on one surface of the substrate SUB where the barrier layer BRL is provided. The panel circuit layer PCL may include circuit elements including the pixel transistors Tpx and the driver transistors Tdr, and wires (e.g., signal lines and power lines). In an embodiment, the panel circuit layer PCL may further include additional conductive pattern layers. For example, the panel circuit layer PCL may further include connection electrodes CNE, bridge pattern layers, or the like.

The panel circuit layer PCL may further include insulating layers disposed on the substrate SUB. For example, the panel circuit layer PCL may include a first insulating layer INS1, a second insulating layer INS2, an interlayer insulating layer ILD, and a first passivation layer PSV1 that are sequentially disposed on the substrate SUB along the third direction D3. In an embodiment, the panel circuit layer PCL may selectively further include the connection electrodes CNE and a second passivation layer PSV2 disposed on the first passivation layer PSV1. In an embodiment, at least one of the first passivation layer PSV1 or the second passivation layer PSV2 may have a multilayer structure including an inorganic layer and an organic layer. For example, the first passivation layer PSV1 may include a first inorganic layer IOL1 and a first organic layer ORL1 sequentially disposed on the interlayer insulating layer ILD, and the second passivation layer PSV2 may include a second inorganic layer IOL2 and a second organic layer ORL2 sequentially disposed on the first passivation layer PSV1.

In an embodiment, the panel circuit layer PCL may further include gate insulating pattern layers. For example, the panel circuit layer PCL may further include a first gate insulating pattern layer GI1 disposed between a first semiconductor pattern layer ACT1 and a first gate electrode GE1 of each first transistor TFT1, and a second gate insulating pattern layer GI2 disposed between a second semiconductor pattern layer ACT2 and a second gate electrode GE2 of each second transistor TFT2.

In FIG. 6, the display panel 110 having a structure in which the first gate insulating pattern layer GI1 and the second gate insulating pattern layer GI2 are etched in a pattern layer of islands positioned locally only on a part of the first semiconductor pattern layer ACT1 and a part of the second semiconductor pattern layer ACT2, respectively, was illustrated. For example, the first gate insulating pattern layer GI1 may cover only a part of the first semiconductor pattern layer ACT1 to cover a first channel region CH1 and expose a first drain region DR1 and a first source region SR1. For example, the first gate electrode GE1 and the first gate insulating pattern layer GI1 may be etched using a mask (e.g., single mask). Accordingly, the first gate insulating pattern layer GI1 may have a shape and a size corresponding to those of the first gate electrode GE1. For example, the first gate insulating pattern layer GI1 may be disposed on a part (for example, the first channel region CH1 under the first gate electrode GE1) of the first semiconductor pattern layer ACT1, and may expose the other part (for example, the first drain region DR1 and the first source region SR1) of the first semiconductor pattern layer ACT1. For example, the second gate insulating pattern layer GI2 may cover only a part of the second semiconductor pattern layer ACT2 to cover the second channel region CH2 and expose the second drain region DR2 and the second source region SR2. For example, the second gate electrode GE2 and the second gate insulating pattern layer GI2 may be etched using a mask (e.g., single mask). Accordingly, the second gate insulating pattern layer GI2 may have a shape and a size corresponding to a shape and a size of the second gate electrode GE2. For example, the second gate insulating pattern layer GI2 may be disposed on a part (for example, the second channel region CH2 under the second gate electrode GE2) of the second semiconductor pattern layer ACT2, and may expose the other part (for example, the second drain region DR2 and the second source region SR2) of the second semiconductor pattern layer ACT2.

However, the shapes of the first gate insulating pattern layer GI1 and the second gate insulating pattern layer GI2 are not limited to the embodiment shown in FIG. 6. For example, at least one of the first gate insulating pattern layer GI1 or the second gate insulating pattern layer GI2 may be formed in (e.g., entirely in) the display area DA and/or the non-display area NDA.

In an embodiment, the first insulating layer INS1, the second insulating layer INS2, the first gate insulating pattern layer GI1, the second gate insulating pattern layer GI2, the interlayer insulating layer ILD, the first inorganic layer IOL1, and the second inorganic layer IOL2 may include at least one inorganic insulating layer including an inorganic insulating material (for example, silicon nitride, silicon oxide, silicon oxynitride, titanium oxide, aluminum oxide, or another inorganic insulating material). The first organic layer ORL1 and the second organic layer ORL2 may include at least one organic insulating layer including an organic insulating material (e.g., acrylic resin, epoxy resin, phenolic resin, polyamide resin, polyimide resin, or another organic insulating material). The surfaces (for example, top surfaces) of the first organic layer ORL1 and the second organic layer ORL2 may be substantially flat. The types, materials, shapes and/or structures of the insulating layers and/or the insulating pattern layers provided in the panel circuit layer PCL may be variously changed according to embodiments.

The pixel transistors Tpx may be included in the pixel circuit PC of each pixel PX, and may be positioned in the display area DA. For example, each pixel transistor Tpx may be disposed in the pixel area PXA in which the corresponding pixel PX is disposed or formed. In FIG. 6, on behalf of the pixel transistors Tpx, any one pixel transistor Tpx (e.g., the first pixel transistor T1 connected to the light emitting element ED of the corresponding pixel PX) is illustrated, and this will be referred to as “first transistor TFT1.” In an embodiment, the first transistor TFT1 may refer to at least one pixel transistor Tpx including the first lower electrode BG1 formed as (e.g., provided in) the first conductive layer CDLI among the pixel transistors Tpx.

The driver transistors Tdr may be included in the driving circuit 121 of the first driver 120. Each driver transistor Tdr may be disposed in the driving circuit area DRA in which the corresponding stage ST is disposed or formed. In an embodiment, the driving circuit area DRA may be positioned in the non-display area NDA. In FIG. 6, on behalf of the driver transistors Tdr, any one driver transistor Tdr (e.g., any one of the fifth to eighth driver transistors Tdr included in the output unit 540 of the n^{th} stage STn) is illustrated, and this will be referred to as “second transistor TFT2”). In an embodiment, the second transistor TFT2 may refer to at least one driver transistor Tdr including the second lower electrode BG2 formed as (e.g., provided in) the second conductive layer CDL2 among the driver transistors Tdr.

In embodiments, the display panel 110 may include the transistors TFT having different structures in relation to the lower electrodes. For example, the first transistor TFT1 and the second transistor TFT2 may have different structures in relation to the lower electrodes.

In an embodiment, some pixel transistors Tpx including the first pixel transistor T1 of FIG. 3, or all the pixel transistors Tpx disposed in the display area DA may include the first lower electrode BG1 formed as (e.g., provided in) the first conductive layer CDL1, similarly to the first transistor TFT1 of FIG. 6. In an embodiment, some driver transistors Tdr including at least one of the fifth to eighth driver transistors M5 to M8 of FIG. 5, or all the driver transistors Tdr disposed in the driving circuit area DRA may include the second lower electrode BG2 formed as (e.g., provided in) the second conductive layer CDL2, similarly to the second transistor TFT2 of FIG. 6. The second conductive layer CDL2, which is a conductive layer disposed on a different layer from the first conductive layer CDL1 on the substrate SUB, may be disposed closer to a semiconductor layer SCL including semiconductor pattern layers of the transistors TFT compared to the first conductive layer CDL1.

The first transistor TFT1 may include the first lower electrode BG1, the first semiconductor pattern layer ACT1 (also referred to as “first active pattern layer”), and the first gate electrode GE1. In an embodiment, the first transistor TFT1 may further include the first drain electrode DE1 and the first source electrode SE1 connected to different parts of the first semiconductor pattern layer ACT1. In another embodiment, the first transistor TFT1 may not include a separate drain electrode and/or a separate source electrode, and the first drain region DR1 and/or the first source region SR1 of the first semiconductor pattern layer ACT1 may be connected to another circuit element, wire, and/or conductive pattern layer to function as the drain electrode and/or the source electrode of the first transistor TFT1.

The first lower electrode BG1 may be formed as (e.g., provided in) the first conductive layer CDL1 on the substrate SUB. In an embodiment, the first conductive layer CDL1 may be disposed between the substrate SUB and the first insulating layer INS1. For example, the first conductive layer CDL1 may be disposed on the barrier layer BRL, and may be covered by the first insulating layer INS1.

The first lower electrode BG1 may overlap the first semiconductor pattern layer ACT1. For example, the first lower electrode BG1 may be disposed under the first semiconductor pattern layer ACT1 to overlap at least the first channel region CH1. The first insulating layer INS1 and the second insulating layer INS2 may be interposed between the first lower electrode BG1 and the first semiconductor pattern layer ACT1. For example, the first lower electrode BG1 and the first semiconductor pattern layer ACT1 may be spaced apart from each other by a first distance d1 with the first insulating layer INS1 and the second insulating layer INS2 disposed between the first lower electrode BG1 and the first semiconductor pattern layer ACT1. In an embodiment, the first distance dl may correspond to the sum (for example, about 3000 Å) of the thickness (for example, about 2000 Å) of the first insulating layer INS1 and the thickness (for example, about 1000 Å) of the second insulating layer INS2. The first lower electrode BG1 may face the first gate electrode GE1. The first semiconductor pattern layer ACT1 may be disposed between the first lower electrode BG1 and the first gate electrode GE1.

The first lower electrode BG1 may or may not be connected to an electrode of the first transistor TFT1. For example, the first lower electrode BG1 may be connected to an electrode of the first transistor TFT1, and may function as a back-gate electrode (or a bottom-gate electrode) that adjusts the characteristics of the first transistor TFT1. In an embodiment, the first lower electrode BG1 may be connected to the first source electrode SE1 (or the first source region SR1).

The first semiconductor pattern layer ACT1 may be formed as (e.g., provided in) the semiconductor layer SCL on the substrate SUB. In an embodiment, the semiconductor layer SCL may be disposed on the second insulating layer INS2. For example, the semiconductor layer SCL may be disposed between the second insulating layer INS2 and the interlayer insulating layer ILD.

The first semiconductor pattern layer ACT1 may include the first channel region CH1, and the first source region SR1 and the first drain region DR1 that are spaced apart from each other with the first channel region CH1 disposed between the first source region SR1 and the first drain region DR1. For example, the first source region SR1 and the first drain region DR1 may be positioned at sides (e.g., opposite sides) of the first channel region CH1. The first channel region CH1 may be a region that maintains semiconductor characteristics without becoming conductive, and the first source region SR1 and the first drain region DR1 may be regions having conductivity.

The first semiconductor pattern layer ACT1 may overlap the first lower electrode BG1 and the first gate electrode GE1. For example, a part of the first semiconductor pattern layer ACT1 including the first channel region CH1 may overlap the first lower electrode BG1 and the first gate electrode GE1.

The first gate electrode GE1 (or a top-gate electrode) may be formed as (e.g., provided in) the third conductive layer CDL3 on the substrate SUB. In an embodiment, the third conductive layer CDL3 may be disposed on the semiconductor layer SCL including the first semiconductor pattern layer ACT1 and an insulating layer (or a third insulating layer INS3) including the first gate insulating pattern layer GI1. The third conductive layer CDL3 may be covered by the interlayer insulating layer ILD.

The first gate electrode GE1 may be disposed on the first semiconductor pattern layer ACT1 to overlap the first channel region CH1. The first gate electrode GE1 and the first semiconductor pattern layer ACT1 may be separated and/or spaced apart from each other with the first gate insulating pattern layer GI1 disposed between the first gate electrode GE1 and the first semiconductor pattern layer ACT1.

The first gate insulating pattern layer GI1 may be disposed between the first gate electrode GE1 and the first semiconductor pattern layer ACT1. The first gate insulating pattern layer GI1 may cover a part (for example, the first channel region CH1) of the first semiconductor pattern layer ACT1 that overlaps the first gate electrode GE1.

The first drain electrode DE1 and the first source electrode SE1 may be formed as (e.g., provided in) a fourth conductive layer CDL4 on the substrate SUB. In an embodiment, the fourth conductive layer CDL4 may be disposed on the interlayer insulating layer ILD that covers the third conductive layer CDL3 including the first gate electrode GE1. For example, the fourth conductive layer CDL4 may be disposed between the interlayer insulating layer ILD and the first passivation layer PSV1.

The first drain electrode DE1 may be connected to a part of the first semiconductor pattern layer ACT1. For example, the first drain electrode DE1 may be connected to the first drain region DR1 through at least one contact hole penetrating the interlayer insulating layer ILD.

The first source electrode SE1 may be connected to another part of the first semiconductor pattern layer ACT1. For example, the first source electrode SE1 may be connected to the first source region SR1 through at least one contact hole penetrating the interlayer insulating layer ILD. In an embodiment, the first source electrode SE1 may be further connected to the first lower electrode BG1. For example, the first source electrode SE1 may be connected to the first lower electrode BG1 through at least one contact hole penetrating the first insulating layer INS1, the second insulating layer INS2, and the interlayer insulating layer ILD.

The second transistor TFT2 may include the second lower electrode BG2, the second semiconductor pattern layer ACT2 (also referred to as “second active pattern layer”), and the second gate electrode GE2. In an embodiment, the second transistor TFT2 may further include a second drain electrode DE2 and a second source electrode SE2 connected to different parts of the second semiconductor pattern layer ACT2. In another embodiment, the second transistor TFT2 may not include a separate drain electrode and/or a separate source electrode, and the second drain region DR2 and/or the second source region SR2 of the second semiconductor pattern layer ACT2 may be connected to another circuit element, wire, and/or conductive pattern layer to function as the drain electrode and/or the source electrode of the second transistor TFT2.

The second lower electrode BG2 may be formed as (e.g., provided in) the second conductive layer CDL2 on the substrate SUB. In an embodiment, the second conductive layer CDL2 may be disposed on the first insulating layer INS1 that covers the first lower electrode BG1. For example, the second conductive layer CDL2 may be disposed between the first insulating layer INS1 and the second insulating layer INS2.

The second lower electrode BG2 may overlap the second semiconductor pattern layer ACT2. For example, the second lower electrode BG2 may be disposed under the second semiconductor pattern layer ACT2 to overlap at least the second channel region CH2. The second insulating layer INS2 may be interposed between the second lower electrode BG2 and the second semiconductor pattern layer ACT2. For example, the second lower electrode BG2 and the second semiconductor pattern layer ACT2 may be spaced apart from each other by a second distance d2 with the second insulating layer INS2 disposed between the second lower electrode BG2 and the second semiconductor pattern layer ACT2. In an embodiment, the second distance d2 may correspond to the thickness (for example, about 1000 Å) of the second insulating layer INS2, and may be smaller than the first distance d1. The second lower electrode BG2 may face the second gate electrode GE2 with the second semiconductor pattern layer ACT2 disposed between the second lower electrode BG2 and the second gate electrode GE2.

The second lower electrode BG2 may or may not be connected to an electrode of the second transistor TFT2. For example, the second lower electrode BG2 may be connected to an electrode (for example, the second gate electrode GE2) of the second transistor TFT2, may function as a back-gate electrode (for example, a second back-gate electrode) that adjusts the characteristics of the second transistor TFT2.

The second semiconductor pattern layer ACT2 may be formed as (e.g., provided in) the semiconductor layer SCL on the substrate SUB. In an embodiment, the first semiconductor pattern layer ACT1 and the second semiconductor pattern layer ACT2 may be provided and/or disposed on the same layer (for example, the same semiconductor layer SCL) on the substrate SUB. For example, the second semiconductor pattern layer ACT2 may be disposed between the second insulating layer INS2 and the interlayer insulating layer ILD.

The second semiconductor pattern layer ACT2 may include the second channel region CH2, and the second source region SR2 and the second drain region DR2 that are spaced apart from each other with the second channel region CH2 disposed between the second source region SR2 and the second drain region DR2. For example, the second source region SR2 and the second drain region DR2 may be positioned at sides (e.g., opposite sides) of the second channel region CH2. The second channel region CH2 may be a region that maintains semiconductor characteristics without becoming conductive, and the second source region SR2 and the second drain region DR2 may be regions having conductivity.

The second semiconductor pattern layer ACT2 may overlap the second lower electrode BG2 and the second gate electrode GE2. For example, a part of the second semiconductor pattern layer ACT2 including the second channel region CH2 may overlap the second lower electrode BG2 and the second gate electrode GE2.

The second gate electrode GE2 may be formed as (e.g., provided in) the third conductive layer CDL3 on the substrate SUB. In an embodiment, the first gate electrode GE1 and the second gate electrode GE2 may be provided and/or disposed on the same layer (for example, the same third conductive layer CDL3) on the substrate SUB. For example, the second gate electrode GE2 may be disposed between the insulating layer (or the third insulating layer INS3) including the first and second gate insulating pattern layers GI1 and GI2 and the interlayer insulating layer ILD.

The second gate electrode GE2 may be disposed on the second semiconductor pattern layer ACT2 to overlap the second channel region CH2. The second gate electrode GE2 and the second semiconductor pattern layer ACT2 may be separated and/or spaced apart from each other with the second gate insulating pattern layer GI2 disposed between the second gate electrode GE2 and the second semiconductor pattern layer ACT2.

The second gate insulating pattern layer GI2 may be disposed between the second gate electrode GE2 and the second semiconductor pattern layer ACT2. The second gate insulating pattern layer GI2 may cover a part (for example, the second channel region CH2) of the second semiconductor pattern layer ACT2 that overlaps the second gate electrode GE2.

The second drain electrode DE2 and the second source electrode SE2 may be formed as (e.g., provided in) the fourth conductive layer CDL4 on the substrate SUB. In an embodiment, the second drain electrode DE2, the second source electrode SE2, the first drain electrode DE1, and the first source electrode SE1 may be disposed on the same layer on the substrate SUB. For example, the second drain electrode DE2 and the second source electrode SE2 may be disposed between the interlayer insulating layer ILD and the first passivation layer PSV1. For example, the second drain electrode DE2 and the second source electrode SE2 may be disposed on the interlayer insulating layer ILD that covers the third conductive layer CDL3 including the first gate electrode GE1 and the second gate electrode GE2, and may be covered by the first passivation layer PSV1.

The second drain electrode DE2 may be connected to a part of the second semiconductor pattern layer ACT2. For example, the second drain electrode DE2 may be connected to the second drain region DR2 through at least one contact hole penetrating the interlayer insulating layer ILD.

The second source electrode SE2 may be connected to another part of the second semiconductor pattern layer ACT2. For example, the second source electrode SE2 may be connected to the second source region SR2 through at least one contact hole penetrating the interlayer insulating layer ILD.

The transistors TFT including the first transistors TFT1 of the pixels PX and the second transistors TFT2 of the driving circuit 121 may be covered by at least one passivation layer. For example, the transistors TFT may be covered by the first passivation layer PSV1 and the second passivation layer PSV2.

In an embodiment, at least one first transistor TFT1 provided in each pixel PX may be connected to the light emitting element ED of the corresponding pixel PX through the connection electrode CNE. The connection electrode CNE may be formed as (e.g., provided in) a fifth conductive layer CDL5 on the substrate SUB. In an embodiment, the fifth conductive layer CDL5 may be disposed on the first passivation layer PSV1. For example, the fifth conductive layer CDL5 may be disposed between the first passivation layer PSV1 and the second passivation layer PSV2.

The connection electrode CNE may be connected to an electrode of the first transistor TFT1. For example, the connection electrode CNE may be disposed on the first source electrode SE1, and may be connected to the first source electrode SE1 through at least one contact hole or via hole penetrating the first passivation layer PSV1.

The respective electrodes, conductive pattern layers, and/or wires formed as (e.g., provided in) the conductive layers of the panel circuit layer PCL may include at least one conductive material, and may each have a single layer structure or a multilayer structure. For example, the electrodes, the conductive pattern layers, and/or the wires formed as (e.g., provided in) each of the first conductive layer CDL1, the second conductive layer CDL2, the third conductive layer CDL3, the fourth conductive layer CDL4, and the fifth conductive layer CDL5 may include at least one of molybdenum (Mo), titanium (Ti), aluminum (Al), chromium (Cr), gold (Au), silver (Ag), platinum (Pt), palladium (Pd), nickel (Ni), neodymium (Nd), iridium (Ir), tantalum (Ta), tungsten (W), copper (Cu), magnesium (Mg), or another metal, an alloy thereof, or another conductive material, and may each have a single layer structure or a multilayer structure. In an embodiment, the electrodes, the conductive pattern layers, and/or the wires disposed on the same conductive layer may be simultaneously formed of the same conductive material.

In an embodiment, the semiconductor pattern layers formed as (e.g., provided in) the semiconductor layer SCL may include an oxide semiconductor. For example, each of the first semiconductor pattern layer ACT1 and the second semiconductor pattern layer ACT2 may include at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or another oxide semiconductor. The oxide semiconductor used to form the oxide transistors including the first transistor TFT1 and the second transistor TFT2 is not limited to the above materials, and may be variously changed according to embodiments. Further, at least one of the first transistor TFT1 or the second transistor TFT2 may be formed of a semiconductor material other than an oxide semiconductor.

The light emitting element layer LEL may be disposed on the panel circuit layer PCL, and may be positioned in the display area DA. For example, the light emitting element layer LEL may be disposed on the panel circuit layer PCL in the display area DA.

The light emitting element layer LEL may include the light emitting elements ED of the pixels PX. For example, the light emitting element layer LEL may include a pixel defining layer PDL (also referred to as “bank”) that partitions the emission areas of the pixels PX and the light emitting element ED positioned in each emission area. In an embodiment, the light emitting element layer LEL may further include a spacer SPC disposed on a part of the pixel defining layer PDL.

Each light emitting element ED may include a first electrode ET1 (for example, an anode electrode) connected to at least one pixel transistor Tpx (for example, the first transistor TFT1 of FIG. 6) included in the corresponding pixel PX through at least one connection electrode CNE, and the light emitting layer EML and a second electrode ET2 (for example, a cathode electrode) sequentially disposed on the first electrode ET1. In an embodiment, the light emitting element ED may further includes a first intermediate layer (for example, a hole layer including a hole transporting layer) interposed between the first electrode ET1 and the light emitting layer EML, and a second intermediate layer (for example, an electron layer including an electron transporting layer) interposed between the light emitting layer EML and the second electrode ET2.

The first electrode ET1 of the light emitting element ED may be disposed on the panel circuit layer PCL. For example, the first electrode ET1 may be disposed on the second passivation layer PSV2 to correspond to (or to overlap) each emission area. In an embodiment, the first electrode ET1 may be connected to the connection electrode CNE through at least one contact hole or via hole penetrating the second passivation layer PSV2. In another example, the first electrode ET1 may be directly connected to at least one pixel transistor Tpx without the connection electrode CNE.

The first electrode ET1 may include a conductive material. In an embodiment, the first electrode ET1 may include a metal material having high reflectivity. For example, the first electrode ET1 may have a single-layer structure of molybdenum (Mo), titanium (Ti), copper (Cu) or aluminum (Al), or may have a multilayer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni).

The light emitting layer EML of the light emitting element ED may include a high molecular material or a low molecular material. Light emitted from the light emitting layer EML may be used to display image. In an embodiment, the light emitting layer EML may be provided for each pixel PX, and the light emitting layer EML of each pixel PX may emit visible light of a color corresponding to the corresponding pixel PX. In another embodiment, the light emitting layer EML may be a common layer shared by the pixels PX of different colors, and a wavelength conversion layer and/or color filters corresponding to the color (or wavelength band) of light desired to be emitted from each pixel PX may be arranged in the emission areas of at least some of the pixels PX.

The second electrode ET2 of the light emitting element ED may include a conductive material. In an embodiment, the second electrode ET2 may be a common layer formed across the entire display area DA to cover the light emitting layer EML and the pixel defining layer PDL. In an embodiment, the second electrode ET2 may be formed of a transparent conductive material (TCO) such as ITO, IZO, ZnO, or ITZO capable of transmitting light or a semi-transmissive conductive material such as magnesium (Mg), silver (Ag), or an alloy of magnesium (Mg) and silver (Ag).

The pixel defining layer PDL may have an opening corresponding to each emission area and may surround the emission area. For example, the pixel defining layer PDL may be formed to cover an edge portion of the first electrode ET1 of the light emitting element ED and may include an opening exposing the remaining portion of the first electrode ET1. A region where the exposed first electrode ET1 and the light emitting layer EML overlap (or a region including the same) may be defined as the emission area of each pixel PX.

In an embodiment, the pixel defining layer PDL may include at least one organic insulating layer including an organic insulating material. For example, the pixel defining layer PDL may include acrylic resin, epoxy resin, phenolic resin, polyamide resin, polyimide resin, unsaturated polyester resin, polyphenylene ether resin, polyphenylenesulfide resin and benzocyclobutene (BCB) or other organic insulating materials.

The spacer SPC may be disposed on a part of the pixel defining layer PDL. The spacer SPC may include at least one organic insulating layer including an organic insulating material. The spacer SPC and the pixel defining layer PDL may include the same material, or may include different materials. In an embodiment, the pixel defining layer PDL and the spacer SPC may be sequentially formed through separate mask processes. In another embodiment, the pixel defining layer PDL and the spacer SPC may be simultaneously formed using a halftone mask. For example, the pixel defining layer PDL and the spacer SPC may be formed as a single insulating layer that is integral with each other.

The encapsulation layer ENL may be disposed on the light emitting element layer LEL. The encapsulation layer ENL may cover the light emitting element layer LEL in the display area DA and may extend to the non-display area NDA to be in contact with the panel circuit layer PCL. For example, the encapsulation layer ENL may be disposed in the display area DA to cover the light emitting element layer LEL, and the end portion of the encapsulation layer ENL may be positioned in a part of the non-display area NDA adjacent to the display area DA. The encapsulation layer ENL may block the permeation of oxygen or moisture into the light emitting element layer LEL, and may reduce electrical and/or physical impacts to the panel circuit layer PCL and the light emitting element layer LEL.

In an embodiment, the encapsulation layer ENL may have a multilayer structure including a first encapsulation layer ENL1, a second encapsulation layer ENL2, and a third encapsulation layer ENL3 sequentially disposed on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material. The structure and/or material of the encapsulation layer ENL may be changed according to embodiments.

As described above, the display panel 110 may include the first conductive layer CDL1 and the second conductive layer CDL2 disposed under the semiconductor layer SCL. For example, the first conductive layer CDL1 and the second conductive layer CDL2, which are disposed and/or formed in different layers on the substrate SUB, may be positioned between the substrate SUB and the semiconductor layer SCL. The first insulating layer INS1 and the second insulating layer INS2 may be disposed between the first conductive layer CDL1 and the semiconductor layer SCL. The second conductive layer CDL2, which is disposed on the first insulating layer INS1 that covers the first conductive layer CDL1, may be disposed closer to the semiconductor layer SCL compared to the first conductive layer CDL1. The second insulating layer INS2 may be disposed between the second conductive layer CDL2 and the semiconductor layer SCL.

In accordance with embodiments, the magnitude (or amount) of the capacitance formed between the lower electrode of each transistor TFT and the semiconductor pattern layer may be differentiated and/or optimized according to the characteristics required for each transistor TFT. For example, by selectively disposing the lower electrode of each transistor TFT on the first conductive layer CDL1 or the second conductive layer CDL2 according to the characteristics required for each transistor TFT, the characteristics of each transistor TFT may be appropriately adjusted and/or optimized.

In embodiments, at least one pixel transistor Tpx that requires more uniform characteristics may be formed of the first transistor TFT1 including the first lower electrode BG1 formed as (e.g., provided in) the first conductive layer CDL1. In the first transistor TFT1, the distance (for example, the first distance d1) between the first semiconductor pattern layer ACT1 and the first lower electrode BG1, and the thickness of the insulating layer (for example, an insulating layer of at least a double layer including the first insulating layer INS1 and the second insulating layer INS2) between the first semiconductor pattern layer ACT1 and the first lower electrode BG1 may be relatively large. In an embodiment, the thicknesses of the first insulating layer INS1 and the second insulating layer INS2 may be appropriately adjusted or set in consideration of the characteristics required for the first transistor TFT1. Accordingly, the capacitance (e.g., parasitic capacitance) formed in the first transistor TFT1 may be reduced or minimized, thereby preventing, reducing, or minimizing variation in the characteristics of the first transistor TFT1. Accordingly, it is possible to prevent, reduce, or minimize blurring of the image due to the luminance variation of the pixels PX, and to improve the image quality of the display device 100.

In embodiments, at least one driver transistor Tdr that requires a higher on-current (for example, a drain-source current in a turn-on state) to stably drive the pixels PX may be formed of the second transistor TFT2 including the second lower electrode BG2 formed as (e.g., provided in) the second conductive layer CDL2. In the second transistor TFT2, the distance (for example, the second distance d2) between the second semiconductor pattern layer ACT2 and the second lower electrode BG2, and the thickness of the insulating layer (for example, the second insulating layer INS2) between the second semiconductor pattern layer ACT2 and the second lower electrode BG2 may be relatively small. In an embodiment, the thickness of the second insulating layer INS2 may be appropriately adjusted or set in consideration of the characteristics required for the second transistor TFT2. Accordingly, the capacitance (e.g., parasitic capacitance) formed in the second transistor TFT2 increases, which makes it possible to appropriately and/or easily increase the on-current of the second transistor TFT2 without changing the length or the width of the second semiconductor pattern layer ACT2. Accordingly, the output characteristics (for example, the switching characteristics and/or the response speed) of the second transistor TFT2 may be improved in case of preventing or minimizing the change in the threshold voltage of the second transistor TFT2. Further, since the output characteristics of the second transistor TFT2 are improved, the output characteristics of the driving circuit 121 may be improved, thereby stably driving the pixels PX.

For example, the display panel 110 according to embodiments may include a relatively large number of conductive layers, including the first conductive layer CDL1 and the second conductive layer CDL2. Accordingly, even in a high-resolution panel, a sufficient design space for forming pixel circuits PC and/or wires may be ensured. For example, even in a high-resolution panel where the areas of the pixel area PXA and a wiring area are small, it is possible to sufficiently ensure the capacitance of the pixel capacitors Cpx, and to stably design wires by appropriately arranging the respective electrodes and/or the respective wires on the plurality of conductive layers.

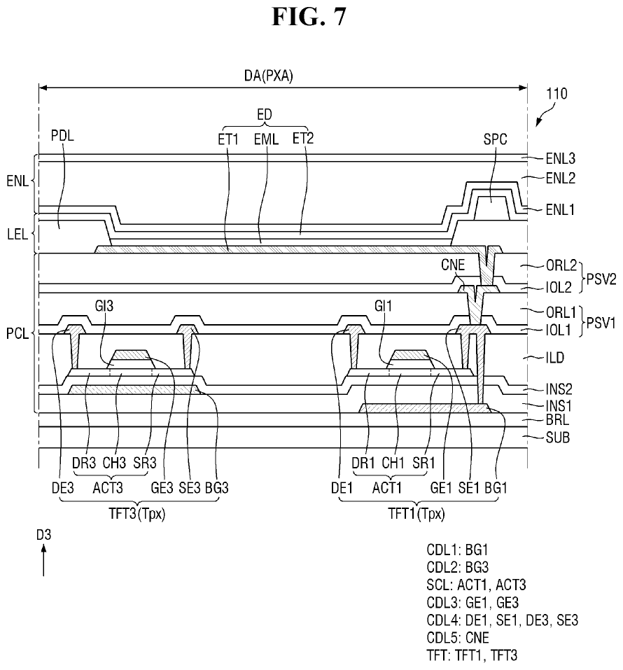

FIG. 7 is a schematic cross-sectional view illustrating the display panel 110 according to an embodiment. For example, FIG. 7 shows a part of the display area DA of the display panel 110.

In FIG. 7, the first transistor TFT1 and the third transistor TFT3 provided in each pixel area PXA and having different structures in relation to the lower electrode are shown as an example of circuit elements that are provided or disposed on the panel circuit layer PCL of the display panel 110. For example, the pixel transistors Tpx of each pixel PX may include the first transistor TFT1 including the first lower electrode BG1 and the third transistor TFT3 including the third lower electrode BG3. In describing the embodiment of FIG. 7, like reference numerals will be given to similar or like parts as those of the embodiment of FIG. 6, and redundant description will be omitted for descriptive convenience.

Referring to FIG. 7 in addition to FIGS. 1 to 6, the pixel PX may include the first transistor TFT1 and the third transistor TFT3 having different structures. For example, some of the pixel transistors Tpx provided in each pixel PX may include the first lower electrode BG1 formed as (e.g., provided in) the first conductive layer CDL1, similarly to the first transistor TFT1, and some others of the pixel transistors Tpx may include the third lower electrode BG3 formed as (e.g., provided in) the second conductive layer CDL2, similarly to the third transistor TFT3.

In an embodiment, each pixel transistor Tpx may be formed in the same structure as the first transistor TFT1 or in the same structure as the third transistor TFT3 in consideration of the operating characteristics or the reliability required of each pixel transistor Tpx. For example, the pixel transistor Tpx (for example, the first pixel transistor T1 of FIG. 3) of which luminance is highly likely to change due to changes or variation in the capacitance may be formed in a structure in which the capacitance may be reduced or minimized, similarly to the first transistor TFT1, and the pixel transistor Tpx (for example, at least one of the second to fifth pixel transistors T2 to T5 of FIG. 3) that requires a high-speed switching operation may be formed in a structure in which the switching characteristics may be improved by increasing the capacitance, similarly to the third transistor TFT3.

The third transistor TFT3 may include a third lower electrode BG3, a third semiconductor pattern layer ACT3 (also referred to as “third active pattern layer”), and a third gate electrode GE3. In an embodiment, the third transistor TFT3 may further include a third drain electrode DE3 and a third source electrode SE3 that are connected to different parts of the third semiconductor pattern layer ACT3. In another embodiment, the third transistor TFT3 may not include a separate drain electrode and/or a separate source electrode, and a third drain region DR3 and/or a third source region SR3 of the third semiconductor pattern layer ACT3 may be connected to another circuit element, wire, and/or conductive pattern layer to function as the drain electrode and/or the source electrode of the third transistor TFT3.

The third lower electrode BG3 may be formed as (e.g., provided in) the second conductive layer CDL2 on the substrate SUB. The third lower electrode BG3 may overlap the third semiconductor pattern layer ACT3. For example, the third lower electrode BG3 may be disposed under the third semiconductor pattern layer ACT3 to overlap at least a third channel region CH3. The second insulating layer INS2 may be interposed between the third lower electrode BG3 and the third semiconductor pattern layer ACT3. For example, the third lower electrode BG3 and the third semiconductor pattern layer ACT3 may be spaced apart from each other by a distance corresponding to a thickness (for example, about 1000 Å) of the second insulating layer INS2 with the second insulating layer INS2 disposed between the third lower electrode BG3 and the third semiconductor pattern layer ACT3. The third lower electrode BG3 may face the third gate electrode GE3 with the third semiconductor pattern layer ACT3 disposed between the third lower electrode BG3 and the third gate electrode GE3.

The third lower electrode BG3 may or may not be connected to an electrode of the third transistor TFT3. For example, the third lower electrode BG3 may be connected to an electrode (for example, the third gate electrode GE3) of the third transistor TFT3, and may function as a back-gate electrode (for example, a third back-gate electrode) that adjusts the characteristics of the third transistor TFT3.

The third semiconductor pattern layer ACT3 may be formed as (e.g., provided in) the semiconductor layer SCL on the substrate SUB. In an embodiment, the first semiconductor pattern layer ACT1 and the third semiconductor pattern layer ACT3 may be provided and/or disposed on the same semiconductor layer SCL on the substrate SUB.

The third semiconductor pattern layer ACT3 may include the third channel region CH3, and the third source region SR3 and the third drain region DR3 that are spaced apart from each other with the third channel region CH3 disposed between the third source region SR3 and the third drain region DR3. For example, the third source region SR3 and the third drain region DR3 may be positioned on sides (e.g., opposite sides) of the third channel region CH3. The third channel region CH3 may be a region that maintains semiconductor characteristics without becoming conductive, and the third source region SR3 and the third drain region DR3 may be regions having conductivity.

The third semiconductor pattern layer ACT3 may overlap the third lower electrode BG3 and the third gate electrode GE3. For example, a part of the third semiconductor pattern layer ACT3 including the third channel region CH3 may overlap the third lower electrode BG3 and the third gate electrode GE3.

The third gate electrode GE3 may be formed as (e.g., provided in) the third conductive layer CDL3 on the substrate SUB. For example, the third gate electrode GE3 and the first gate electrode GE1 may be provided and/or disposed on the same layer on the substrate SUB.

The third gate electrode GE3 may be disposed on the third semiconductor pattern layer ACT3 to overlap the third channel region CH3. The third gate electrode GE3 and the third semiconductor pattern layer ACT3 may be separated and/or spaced apart from each other with the third gate insulating pattern layer GI3 disposed between the third gate electrode GE3 and the third semiconductor pattern layer ACT3.

The third gate insulating pattern layer GI3 may be disposed between the third gate electrode GE3 and the third semiconductor pattern layer ACT3. The third gate insulating pattern layer GI3 may cover a part (for example, the third channel region CH3) of the third semiconductor pattern layer ACT3 that overlaps the third gate electrode GE3.

The third drain electrode DE3 and the third source electrode SE3 may be formed as (e.g., provided in) the fourth conductive layer CDL4 on the substrate SUB. In an embodiment, the third drain electrode DE3, the third source electrode SE3, the first drain electrode DE1, and the first source electrode SE1 may be disposed on the same layer on the substrate SUB.

The third drain electrode DE3 may be connected to a part of the third semiconductor pattern layer ACT3. For example, the third drain electrode DE3 may be connected to the third drain region DR3 through at least one contact hole penetrating the interlayer insulating layer ILD.

The third source electrode SE3 may be connected to another part of the third semiconductor pattern layer ACT3. For example, the third source electrode SE3 may be connected to the third source region SR3 through at least one contact hole penetrating the interlayer insulating layer ILD.

In accordance with the above-described embodiment, the magnitude (or amount) of the capacitance (e.g., parasitic capacitance) formed in the pixel transistors Tpx may be differentiated and/or optimized according to the operating characteristics or the reliability required for each pixel transistor Tpx. For example, by selectively arranging the lower electrode of each pixel transistor Tpx on the first conductive layer CDL1 or the second conductive layer CDL2 according to the characteristics required for each pixel transistor Tpx, the characteristics of the pixel transistor Tpx may be appropriately adjusted and/or optimized.

In an embodiment, the magnitude (or amount) of the capacitance (e.g., parasitic capacitance) formed in the driver transistors Tdr may be differentiated and/or optimized in the same manner as that in the embodiment of FIG. 7. For example, in case that it is desirable to reduce the magnitude (or amount) of the capacitance (e.g., parasitic capacitance) formed in at least one driver transistor Tdr, the lower electrode provided in the at least one driver transistor Tdr may be disposed on the first conductive layer CDL1, and the lower electrodes provided in the other driver transistors Tdr may be disposed on the second conductive layer CDL2.

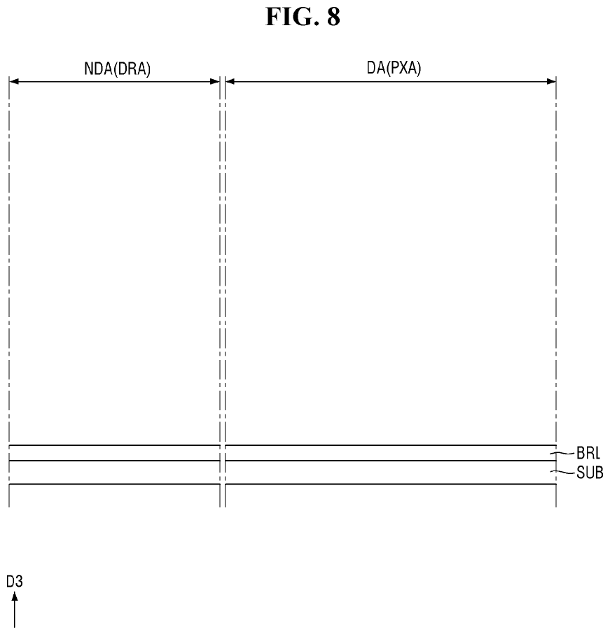

FIGS. 8 to 18 are schematic cross-sectional views showing a method of manufacturing the display device 100 according to an embodiment. For example, FIGS. 8 to 18 sequentially illustrate steps of forming the panel circuit layer PCL according to an embodiment among steps of manufacturing the display panel 110 of FIG. 6.

Referring to FIG. 8 in addition to FIGS. 1 to 7, the substrate SUB including the display area DA and the non-display area NDA may be provided. In an embodiment, the display area DA defined on the substrate SUB may include the pixel area PXA, and the non-display area NDA may include the driving circuit area DRA.

In an embodiment, the barrier layer BRL may be formed on the substrate SUB. The barrier layer BRL may be formed in the display area DA and the non-display area NDA. The barrier layer BRL may be formed by an insulating film forming process (for example, a deposition process) using at least one insulating material (for example, an inorganic insulating material) above. Materials and/or methods for forming the barrier layer BRL may be variously changed according to embodiments.

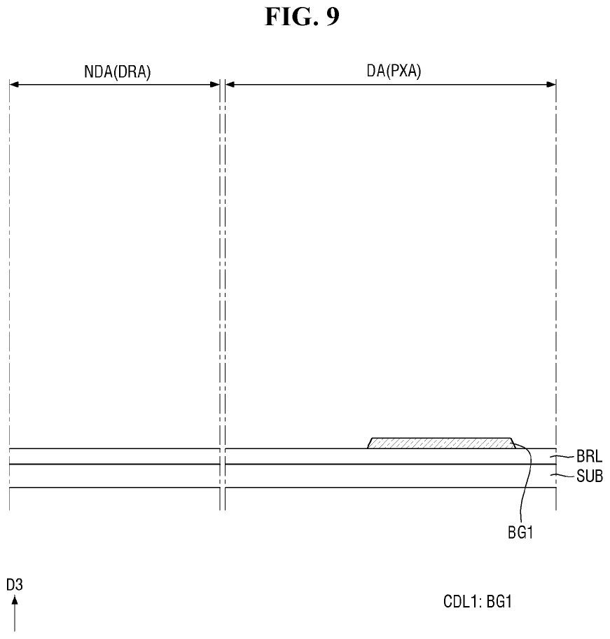

Referring to FIG. 9 in addition to FIGS. 1 to 8, the first lower electrode BG1 may be formed on the substrate SUB (for example, on the barrier layer BRL) in the display area DA. For example, at least one first lower electrode BG1 may be formed in each pixel area PXA. The first lower electrode BG1 may be formed by a conductive film forming process (for example, a deposition process) using at least one conductive material above and a conductive film patterning process (for example, an etching process). Materials and/or methods for forming the first lower electrode BG1 may be variously changed according to embodiments.

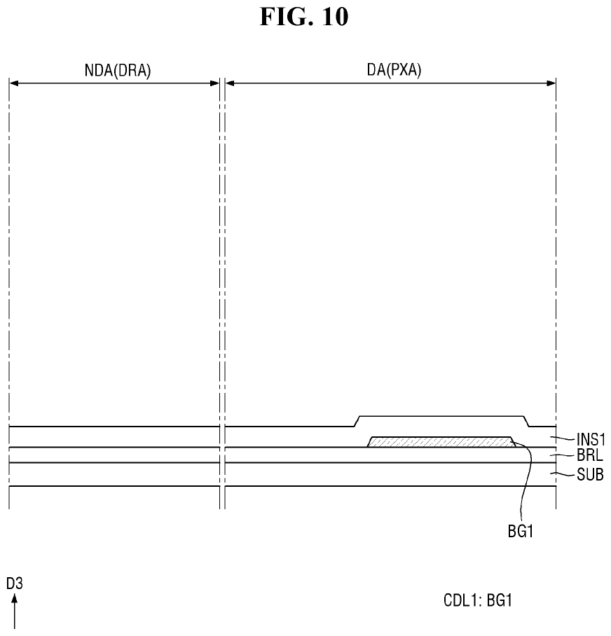

Referring to FIG. 10 in addition to FIGS. 1 to 9, the first insulating layer INS1 that covers the first lower electrode BG1 may be formed on the substrate SUB. The first insulating layer INS1 may be formed in the display area DA and the non-display area NDA (for example, the driving circuit area DRA). The first insulating layer INS1 may be formed by an insulating film forming process using at least one insulating material (for example, an inorganic insulating material) above. Materials and/or methods for forming the first insulating layer INS1 may be variously changed according to embodiments.

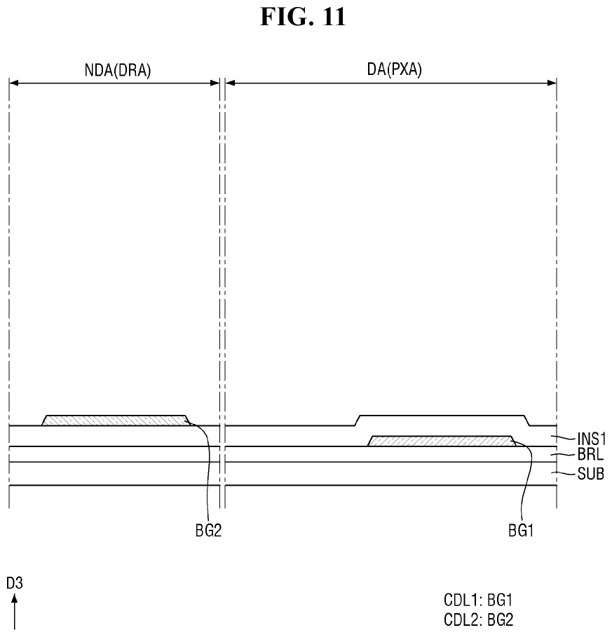

Referring to FIG. 11 in addition to FIGS. 1 to 10, the second lower electrode BG2 may be formed on the first insulating layer INS1 in the driving circuit area DRA. For example, at least one second lower electrode BG2 may be formed in each stage area where each stage ST of the driving circuit 121 is disposed. The second lower electrode BG2 may be formed by the conductive film forming process using at least one conductive material above and the conductive film patterning process. Materials and/or methods for forming the second lower electrode BG2 may be variously changed according to embodiments.

In an embodiment, in case that the pixel PX includes the third transistor TFT3 shown in FIG. 7, the second lower electrode BG2 may be formed in the driving circuit area DRA and, at the same time, the third lower electrode BG3 may be formed in each pixel area PXA.

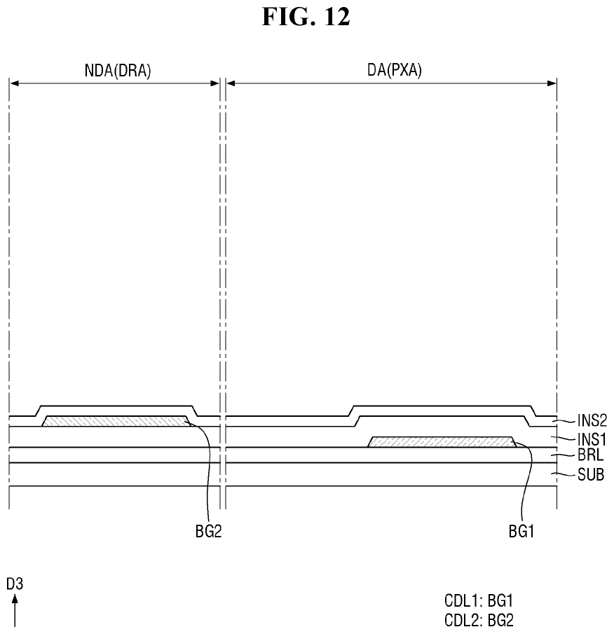

Referring to FIG. 12 in addition to FIGS. 1 to 11, the second insulating layer INS2 that covers the second lower electrode BG2 may be formed on the first insulating layer INS1. The second insulating layer INS2 may be formed in the display area DA and the non-display area NDA (for example, the driving circuit area DRA). The second insulating layer INS2 may be formed by an insulating film forming process using at least one insulating material (for example, an inorganic insulating material) above. Materials and/or methods for forming the second insulating layer INS2 may be variously changed according to embodiments.

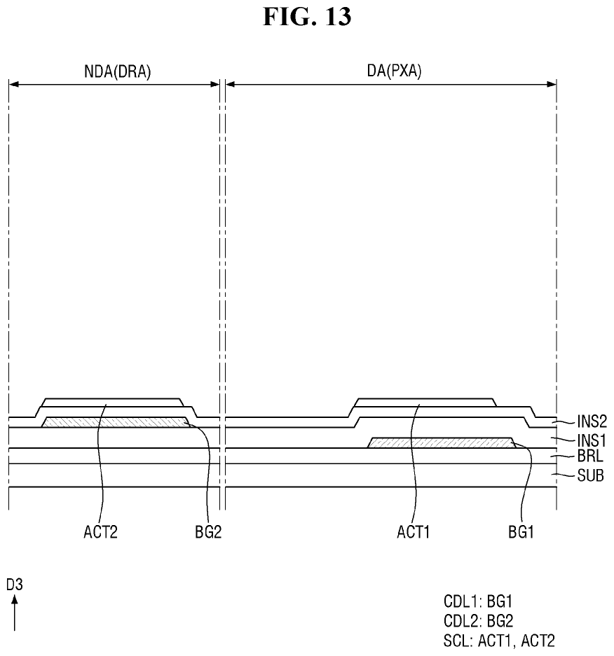

Referring to FIG. 13 in addition to FIGS. 1 to 12, the first semiconductor pattern layer ACT1 and the second semiconductor pattern layer ACT2 may be formed on the second insulating layer INS2. For example, at least one first semiconductor pattern layer ACT1 may be formed in each pixel area PXA, and at least one second semiconductor pattern layer ACT2 may be formed in each stage area of the driving circuit area DRA. Each first semiconductor pattern layer ACT1 may be formed to overlap each first lower electrode BG1, and each second semiconductor pattern layer ACT2 may be formed to overlap each second lower electrode BG2.

In an embodiment, the first semiconductor pattern layer ACT1 and the second semiconductor pattern layer ACT2 may be simultaneously formed of the same oxide semiconductor. For example, the first semiconductor pattern layer ACT1 and the second semiconductor pattern layer ACT2 may be formed in the pixel area PXA and the driving circuit area DRA, respectively, by a semiconductor film forming process using at least one oxide semiconductor above and a patterning process.

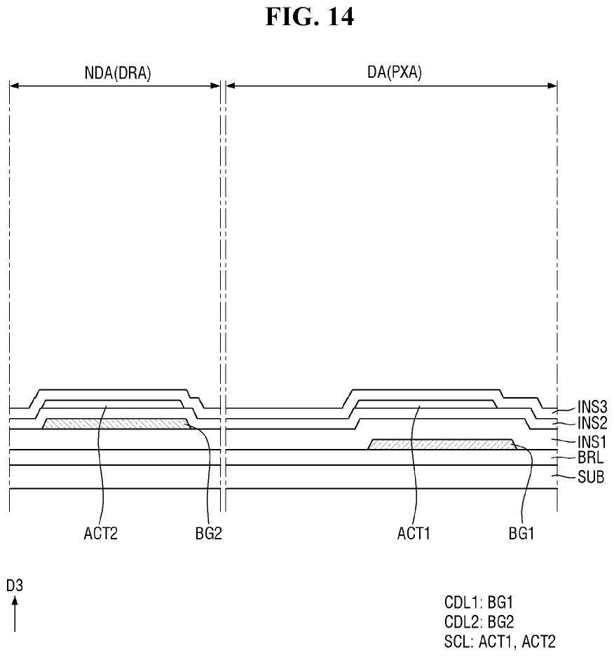

Referring to FIG. 14 in addition to FIGS. 1 to 13, the third insulating layer INS3 that covers the first semiconductor pattern layer ACT1 and the second semiconductor pattern layer ACT2 may be formed on the second insulating layer INS2. The third insulating layer INS3 may be formed in the display area DA and the non-display area NDA (for example, the driving circuit area DRA). The third insulating layer INS3 may be formed by an insulating film forming process using at least one insulating material (for example, an inorganic insulating material) above. Materials and/or methods for forming the third insulating layer INS3 may be variously changed according to embodiments.

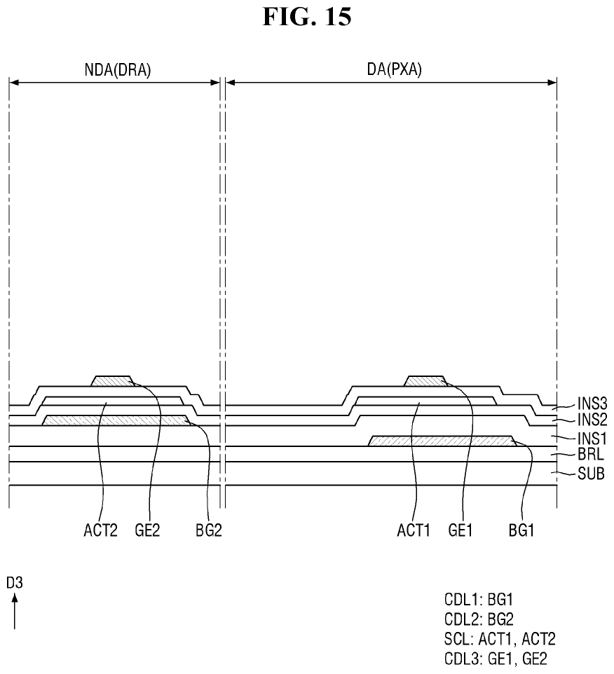

Referring to FIG. 15 in addition to FIGS. 1 to 14, the first gate electrode GE1 and the second gate electrode GE2 may be formed on the third insulating layer INS3. For example, the first gate electrode GE1 may be formed on the first semiconductor pattern layer ACT1 to overlap a part of each first semiconductor pattern layer ACT1 in each pixel area PXA. Further, the second gate electrode GE2 may be formed on the second semiconductor pattern layer ACT2 to overlap a part of each second semiconductor pattern layer ACT2 in each stage area of the driving circuit area DRA.

In an embodiment, the first gate electrode GE1 and the second gate electrode GE2 may be formed by the conductive film forming process using at least one conductive material above and the conductive film patterning process. Materials and/or methods for forming the first gate electrode GE1 and the second gate electrode GE2 may be variously changed according to embodiments.

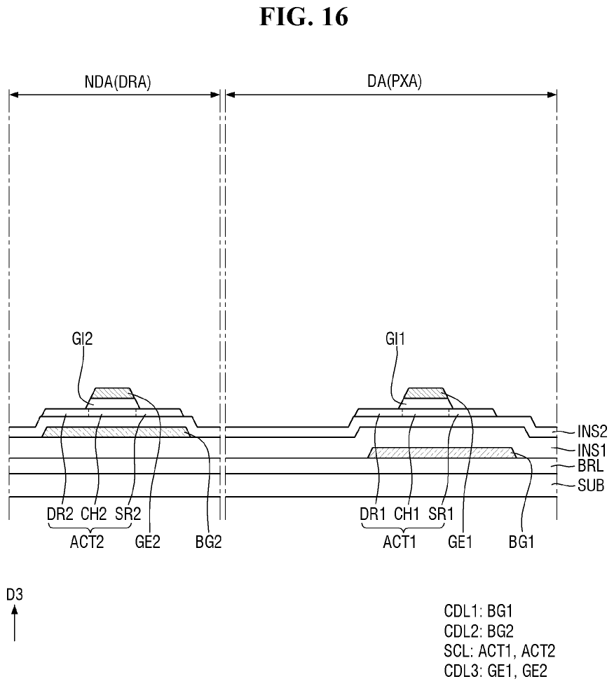

Referring to FIG. 16 in addition to FIGS. 1 to 15, the third insulating layer INS3 may be etched to form the first gate insulating pattern layer GI1 and the second gate insulating pattern layer GI2. For example, the third insulating layer INS3 may be etched with utilizing a mask used for patterning the first gate electrode GE1 and the second gate electrode GE2 or utilizing the first gate electrode GE1 and the second gate electrode GE2 as a mask. Accordingly, the first gate insulating pattern layer GI1 and the second gate insulating pattern layer GI2 may be formed under the first gate electrode GE1 and the second gate electrode GE2, respectively. For example, the first gate insulating pattern layer GI1 may be formed on a part of the first semiconductor pattern layer ACT1 that overlaps the first gate electrode GE1, and the second gate insulating pattern layer GI2 may be formed on a part of the second semiconductor pattern layer ACT2 that overlaps the second gate electrode GE2.

In the process of forming the first gate insulating pattern layer GI1 and the second gate insulating pattern layer G12 by etching the third insulating layer INS3, the properties of the first semiconductor pattern layer ACT1 and the second semiconductor pattern layer ACT2 may be changed such that the first semiconductor pattern layer ACT1 and the second semiconductor pattern layer ACT2 have different characteristics partially. Accordingly, each of the first semiconductor pattern layer ACT1 and the second semiconductor pattern layer ACT2 may be divided into a plurality of regions having different characteristics.

For example, mainly at a part that does not overlap the first gate electrode GE1, an oxide bond may be broken to release oxygen, and oxygen vacancy may occur in the oxide semiconductor constituting the first semiconductor pattern layer ACT1 by an etching gas or the like. Accordingly, the first semiconductor pattern layer ACT1 may be divided into a plurality of regions (for example, the first channel region CH1, the first drain region DR1, and the first source region SR1) having different characteristics. In an embodiment, oxygen vacancy may occur mainly at a part (for example, the first drain region DR1 and the first source region SR1) of the first semiconductor pattern layer ACT1 that does not overlap the first gate electrode GE1, and may diffuse to a part of the region overlapping the first gate electrode GE1.

For example, mainly at a part that does not overlap the second gate electrode GE2, oxygen vacancy may occur in the oxide semiconductor forming the second semiconductor pattern layer ACT2. Accordingly, the second semiconductor pattern layer ACT2 may be divided into a plurality of regions (for example, the second channel region CH2, the second drain region DR2, and the second source region SR2) having different characteristics. In an embodiment, oxygen vacancy may occur mainly at a part (for example, the second drain region DR2 and the second source region SR2) of the second semiconductor pattern layer ACT2 that does not overlap the second gate electrode GE2, and may diffuse to a part of the region overlapping the second gate electrode GE2.

In another embodiment, in the display area DA and/or the driving circuit area DRA, the third insulating layer INS3 may not be etched to correspond to (or to overlap) the first gate electrode GE1 and/or the second gate electrode GE2, and may be formed to cover (e.g., entirely cover) the first semiconductor pattern layer ACT1 and/or the second semiconductor pattern layer ACT2. In an embodiment, the first drain region DR1, the first source region SR1, and the second drain region DR2 and/or the second source region SR2 may become conductive by a doping process utilizing the first gate electrode GE1 and/or the second gate electrode GE2 as a mask. In another example, the doping process may not be performed. For example, hydrogen may flow into the first drain region DR1, the first source region SR1, the second drain region DR2, and the second source region SR2 during a subsequent process of forming the interlayer insulating layer ILD, so that the first drain region DR1, the first source region SR1, the second drain region DR2, and/or the second source region SR2 may become conductive to have relatively low conductivity.

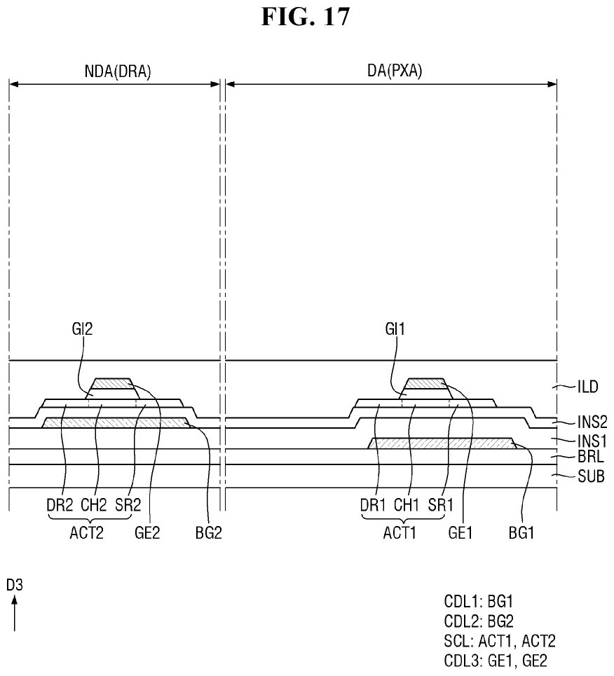

Referring to FIG. 17 in addition to FIGS. 1 to 16, the interlayer insulating layer ILD that covers the first semiconductor pattern layer ACT1, the second semiconductor pattern layer ACT2, the first gate insulating pattern layer GI1, the second gate insulating pattern layer GI2, the first gate electrode GE1, and the second gate electrode GE2 may be formed on the second insulating layer INS2. For example, the interlayer insulating layer ILD may be formed in the display area DA and the non-display area NDA (for example, the driving circuit area DRA). The interlayer insulating layer ILD may be formed by an insulating film forming process using at least one insulating material (for example, an inorganic insulating material) above. Materials and/or methods for forming the interlayer insulating layer ILD may be variously changed according to embodiments.

During the process of forming the interlayer insulating layer ILD, hydrogen may flow into the first semiconductor pattern layer ACT1 and the second semiconductor pattern layer ACT2. In an embodiment, a heat treatment process (for example, annealing) may be additionally performed on the first semiconductor pattern layer ACT1 and the second semiconductor pattern layer ACT2 before or after the formation of the interlayer insulating layer ILD. Even in the heat treatment process, hydrogen may flow into the first semiconductor pattern layer ACT1 and the second semiconductor pattern layer ACT2.

Since hydrogen flows into the first semiconductor pattern layer ACT1 and the second semiconductor pattern layer ACT2, a part of the first semiconductor pattern layer ACT1 and a part of the second semiconductor pattern layer ACT2 may become conductive (for example, conductive to N type) mainly at a part including a large number of oxygen vacancies. For example, the first drain region DR1, the first source region SR1, the second drain region DR2, and the second source region SR2 may become conductive.

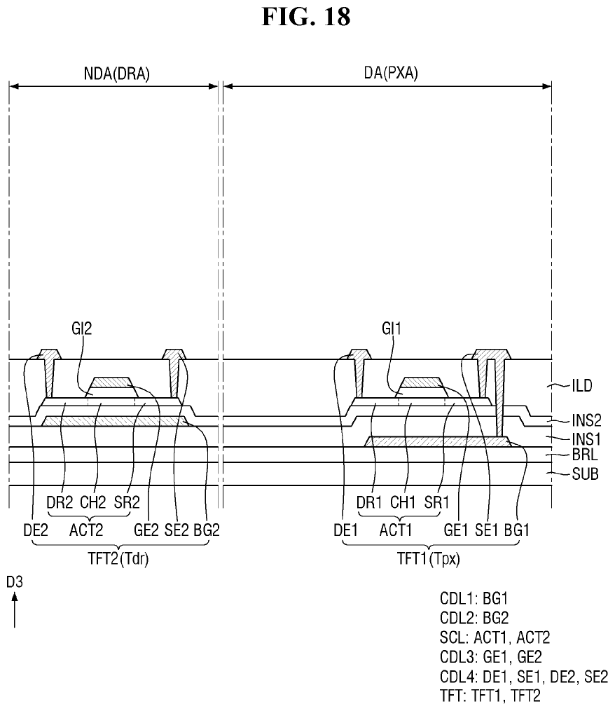

Referring to FIG. 18 in addition to FIGS. 1 to 17, the first drain electrode DE1, the first source electrode SE1, the second drain electrode DE2, and the second source electrode SE2 may be formed on the interlayer insulating layer ILD. In an embodiment, in case that at least one of the first drain region DR1, the first source region SR1, the second drain region DR2, or the second source region SR2 replaces at least one of the first drain electrode DE1, the first source electrode SE1, the second drain electrode DE2, or the second source electrode SE2, at least one of the first drain electrode DE1, the first source electrode SE1, and the second drain electrode DE2, or the second source electrode SE2 may not be formed.

The first drain electrode DE1 and the first source electrode SE1 may be formed to be connected to different parts of the first semiconductor pattern layer ACT1. For example, the first drain electrode DE1 may be formed to be connected to the first drain region DR1, and the first source electrode SE1 may be formed to be connected to the first source region SR1. The second drain electrode DE2 and the second source electrode SE2 may be formed to be connected to different parts of the second semiconductor pattern layer ACT2. For example, the second drain electrode DE2 may be formed to be connected to the second drain region DR2, and the second source electrode SE2 may be formed to be connected to the second source region SR2. For example, contact holes may be formed in the interlayer insulating layer ILD.

By the above-described process, transistors TFT including the first transistor TFT1 and the second transistor TFT2 may be formed in the display area DA and the driving circuit area DRA. Further, in case that the display panel 110 further includes another transistor (for example, the third transistor TFT3 of FIG. 7) that is not shown in FIG. 18, the other transistor may be formed simultaneously with the first transistor TFT1 and/or the second transistor TFT2. For example, elements formed as (e.g., provided in) the same conductive layer or the same semiconductor layer SCL in the display panel 110 may be formed simultaneously.

After the transistors TFT are formed, a process of forming the first passivation layer PSV1 of FIG. 6 may be performed. The first passivation layer PSV1 may cover the transistors TFT. In an embodiment, a process of forming the fifth conductive layer CDL5 including the connection electrode CNE of each pixel PX on the first passivation layer PSV1, and a process of forming the second passivation layer PSV2 that covers the fifth conductive layer CDL5 may be additionally performed. Accordingly, the panel circuit layer PCL of the display panel 110 may be formed.

In an embodiment, in case that the display panel 110 includes the light emitting element layer LEL and the encapsulation layer ENL disposed on the panel circuit layer PCL, the light emitting element layer LEL and the encapsulation layer ENL may be sequentially formed on the panel circuit layer PCL.

In accordance with the display device 100 and the method of manufacturing the same according to the above-described embodiments, the transistors TFT may be formed in different structures according to the operating characteristics and/or performance required for each transistor TFT of the display panel 110. For example, the lower electrode of each transistor TFT may be disposed in the first conductive layer CDLI or the second conductive layer CDL2 according to the operating characteristics and/or performance required for each transistor TFT. Accordingly, the characteristics of the transistors TFT, for example, the characteristics related to a capacitance (or a parasitic capacitance), may be controlled or optimized.

For example, the transistor TFT that requires a relatively low capacitance for stable operation, for example, the first transistor TFT1 included in the pixel transistors Tpx, may be formed to include the first lower electrode BG1 formed as (e.g., provided in) the first conductive layer CDL1. On the other hand, the transistor TFT that requires a relatively high capacitance to ensure a high on-current, for example, the second transistor TFT2 included in the driver transistors Tdr, may be formed to include the second lower electrode BG2 formed as (e.g., provided in) the second conductive layer CDL2. In accordance with the above-described embodiments, the performance of the pixel transistors Tpx and the driver transistors Tdr may be simultaneously improved and/or optimized.

In concluding the detailed description, those skilled in the art will appreciate that many variations and modifications can be made to the embodiments without substantially departing from the principles of the present invention. Therefore, the disclosed embodiments of the invention are used in a generic and descriptive sense only and not for purposes of limitation.

What is claimed is:

1. A display device comprising:
a substrate comprising a display area and a driving circuit area;
a first insulating layer disposed on the substrate;
a second insulating layer disposed on the first insulating layer;
a first transistor disposed in the display area, and comprising a first semiconductor pattern layer formed as a semiconductor layer on the second insulating layer, a first gate electrode disposed on the first semiconductor pattern layer, and a first lower electrode overlapping the first semiconductor pattern layer; and
a second transistor disposed in the driving circuit area, and comprising a second semiconductor pattern layer formed as the semiconductor layer, a second gate electrode disposed on the second semiconductor pattern layer, and a second lower electrode overlapping the second semiconductor pattern layer, wherein
the first lower electrode is formed as a first conductive layer disposed between the substrate and the first insulating layer, and
the second lower electrode is formed as a second conductive layer disposed between the first insulating layer and the second insulating layer.

2. The display device of claim 1, wherein
the first semiconductor pattern layer and the first lower electrode are spaced apart from each other with the first insulating layer and the second insulating layer disposed between the first semiconductor pattern layer and the first lower electrode, and
the second semiconductor pattern layer and the second lower electrode are spaced apart from each other with the second insulating layer disposed between the second semiconductor pattern layer and the second lower electrode.

3. The display device of claim 1, wherein
the first semiconductor pattern layer and the first lower electrode are spaced apart from each other by a first distance, and
the second semiconductor pattern layer and the second lower electrode are spaced apart from each other by a second distance smaller than the first distance.

4. The display device of claim 1, wherein the first semiconductor pattern layer and the second semiconductor pattern layer include an oxide semiconductor.

5. The display device of claim 1, further comprising:
a first gate insulating pattern layer disposed between the first semiconductor pattern layer and the first gate electrode and covering a part of the first semiconductor pattern layer.

6. The display device of claim 5, wherein the first gate insulating pattern layer has a shape and a size corresponding to a shape and a size of the first gate electrode and exposes another part of the first semiconductor pattern layer.

7. The display device of claim 1, further comprising:
a second gate insulating pattern layer disposed between the second semiconductor pattern layer and the second gate electrode and covering a part of the second semiconductor pattern layer.

8. The display device of claim 7, wherein the second gate insulating pattern layer has a shape and a size corresponding to a shape and a size of the second gate electrode and exposes another part of the second semiconductor pattern layer.

9. The display device of claim 1, further comprising:
an interlayer insulating layer covering the first gate electrode and the second gate electrode,
wherein the first transistor further comprises a first source electrode and a first drain electrode disposed on the interlayer insulating layer and connected to different parts of the first semiconductor pattern layer, and
the second transistor further comprises a second source electrode and a second drain electrode disposed on the interlayer insulating layer and connected to different parts of the second semiconductor pattern layer.

10. The display device of claim 9, wherein the first lower electrode is connected to the first source electrode.

11. The display device of claim 1, wherein the second lower electrode is connected to the second gate electrode.

12. The display device of claim 1, further comprising:
a pixel disposed in the display area and comprising the first transistor.

13. The display device of claim 12, wherein the pixel further comprises a third transistor comprising a third semiconductor pattern layer formed as the semiconductor layer, a third gate electrode disposed on the third semiconductor pattern layer, and a third lower electrode formed as the second conductive layer and overlapping the third semiconductor pattern layer.

14. The display device of claim 1, further comprising:
a driving circuit disposed in the driving circuit area and comprising the second transistor.

15. The display device of claim 14, wherein the driving circuit outputs a gate signal that controls an operation of a pixel disposed in the display area.

16. A method of manufacturing a display device, the method comprising:
providing a substrate comprising a display area and a driving circuit area;
forming a first lower electrode on the substrate in the display area;
forming a first insulating layer covering the first lower electrode on the substrate;
forming a second lower electrode on the first insulating layer in the driving circuit area;
forming a second insulating layer covering the second lower electrode on the first insulating layer;
forming a first semiconductor pattern layer overlapping the first lower electrode and a second semiconductor pattern layer overlapping the second lower electrode on the second insulating layer;
forming a third insulating layer covering the first semiconductor pattern layer and the second semiconductor pattern layer on the second insulating layer; and
forming a first gate electrode overlapping the first semiconductor pattern layer and a second gate electrode overlapping the second semiconductor pattern layer on the third insulating layer.

17. The method of claim 16, wherein in the forming of the first semiconductor pattern layer and the second semiconductor pattern layer, the first semiconductor pattern layer and the second semiconductor pattern layer are simultaneously formed of a same oxide semiconductor.

18. The method of claim 16, further comprising:
forming a first gate insulating pattern layer on a part of the first semiconductor pattern layer overlapping the first gate electrode by etching the third insulating layer, and
forming a second gate insulating pattern layer on a part of the second semiconductor pattern layer overlapping the second gate electrode by etching the third insulating layer.

19. The method of claim 16, further comprising:
forming an interlayer insulating layer covering the first gate electrode and the second gate electrode on the second insulating layer.

20. The method of claim 19, further comprising:
forming at least one of a first drain electrode, a first source electrode, a second drain electrode, or a second source electrode, on the interlayer insulating layer, wherein
the first drain electrode and the first source electrode are connected to the first semiconductor pattern layer, and
the second drain electrode and the second source electrode are connected to the second semiconductor pattern layer.
